(19) United States
(12) Patent Application Publication
(10) Pub. No.: US 2025/0176288 A1
(43) Pub. Date: May 29, 2025

(54) PHOTODETECTOR

(71) Applicant: HAMAMATSU PHOTONICS K.K., Hamamatsu-shi (JP)

(72) Inventor: Soh UENOYAMA, Hamamatsu-shi (JP)

(73) Assignee: HAMAMATSU PHOTONICS K.K., Hamamatsu-shi (JP)

(21) Appl. No.: 18/907,842

(22) Filed: Oct. 7, 2024

(30) Foreign Application Priority Data
Nov. 24, 2023 (JP) 2023-198958

(51) Int. Cl. H01L 27/146; G02B 5/00; G02B 5/18

(52) U.S. Cl. CPC H10F 39/806; G02B 5/008; G02B 5/18

(57) ABSTRACT

A photodetector includes an avalanche photodiode having a light incidence surface on which light is incident, and a plasmonic structure diffracting the light by surface plasmon resonance. An avalanche photodiode has a p-type first semiconductor region and an n-type second semiconductor region formed on a side of the first semiconductor region opposite to the light incidence surface to form a pn junction with the first semiconductor region. A plasmonic structure portion has a plurality of unit structures arranged on the first semiconductor region. Each of the plurality of unit structures has a top surface on a side opposite to the light incidence surface, a bottom surface facing the light incidence surface, and a side surface connected to the top surface and the bottom surface. The height of each of the plurality of unit structures is 100 nm or more and 250 nm or less.

### TECHNICAL FIELD

One aspect of the present disclosure relates to a photodetector.

### BACKGROUND

International Publication WO 2017/038542 describes a solid-state imaging device that utilizes avalanche multiplication. International Publication WO 2017/038542 describes that surface plasmon resonance occurs by arranging metal nanoparticles on the surface of a silicon substrate forming a solid-state imaging device (FIG. 23 of International Publication WO 2017/038542).

### SUMMARY

### Technical Problem

The present inventors have found that there is room for improvement in the above-mentioned structure in terms of increasing quantum efficiency. It is an object of one aspect of the present disclosure to provide a photodetector capable of improving quantum efficiency.

### Solution to Problem

A photodetector according to one aspect of the present disclosure is [1] “a photodetector including: an avalanche photodiode including a light incidence surface on which light is incident; and a plasmonic structure portion formed on the light incidence surface to diffract the light by surface plasmon resonance, wherein the avalanche photodiode has a p-type first semiconductor region and an n-type second semiconductor region formed on a side of the first semiconductor region opposite to the light incidence surface to form a pn junction with the first semiconductor region, the plasmonic structure portion includes a plurality of unit structures arranged on the first semiconductor region, each of the plurality of unit structures includes a top surface on a side opposite to the light incidence surface, a bottom surface facing the light incidence surface, and a side surface connected to the top surface and the bottom surface, and a height of each of the plurality of unit structures is 100 nm or more and 250 nm or less”.

In this photodetector, the avalanche photodiode has the p-type first semiconductor region and the n-type second semiconductor region formed on a side of the first semiconductor region opposite to the light incidence surface to form a pn junction with the first semiconductor region. In such a so-called PonN-type structure in which a p-type semiconductor region is formed on an n-type semiconductor region, the amount of light absorption in the p-type semiconductor region tends to be small. In this regard, in this photodetector, the optical path length in the p-type first semiconductor region can be increased by diffracting the incident light using the plasmonic structure portion. As a result, the amount of light absorption can be increased to improve quantum efficiency. In addition, in this photodetector, each unit structure forming the plasmonic structure portion has a top surface, a bottom surface, and a side surface, and the height of each unit structure is 100 nm or more and 250 nm or less. Therefore, since localized surface plasmon resonance can occur in the plasmonic structure portion, incident light can be diffracted appropriately. As a result, the above-described function and effect of increasing the amount of light absorption to improve quantum efficiency can be noticeably achieved. Therefore, according to the photodetector, it is possible to improve quantum efficiency.

The photodetector according to one aspect of the present disclosure may be [2] “the photodetector according to [1], wherein the side surface of each of the plurality of unit structures is formed perpendicular to the light incidence surface, and the height of each of the plurality of unit structures is 100 nm or more and 150 nm or less”. In this case, when the side surface is formed vertically, localized surface plasmon resonance can occur, and accordingly, incident light can be diffracted appropriately.

The photodetector according to one aspect of the present disclosure may be [3] “the photodetector according to [1], wherein the side surface of each of the plurality of unit structures is inclined so as to widen toward the bottom surface”. In this case, the wavelength range in which surface plasmon resonance occurs can be widened. In addition, for example, when a shape defect occurs at the boundary between the top surface and the side surface during the manufacturing process (for example, when corners are chipped or rounded), the desired function may not be achieved. However, when the side surface is inclined, the effect of such a shape defect can be suppressed compared to, for example, when the side surface is formed vertically.

The photodetector according to one aspect of the present disclosure may be [4] “the photodetector according to [3], wherein the height of each of the plurality of unit structures is 125 nm or more and 250 nm or less”. In this case, since localized surface plasmon resonance can occur when the side surface is inclined, incident light can be diffracted appropriately.

The photodetector according to one aspect of the present disclosure may be [5] “the photodetector according to any one of [1] to [4], wherein, in each of the plurality of unit structures, the top surface and the side surface are connected to each other through a curved surface”. In this case, since the plasmonic structure portion is not easily broken even when an external force is applied, it is possible to improve the stability of the photodetector.

The photodetector according to one aspect of the present disclosure may be [6] “the photodetector according to any one of [1] to [5], wherein a silicon dioxide layer is formed between the plasmonic structure portion and the first semiconductor region”. In this case, by adjusting the thickness of the silicon dioxide layer, surface plasmon resonance can occur in a desired wavelength range.

The photodetector according to one aspect of the present disclosure may be [7] “the photodetector according to [6], wherein an adhesion layer formed of a metal material is formed between the plasmonic structure portion and the silicon dioxide layer”. In this case, it is possible to increase the bonding strength between the plasmonic structure portion and the silicon dioxide layer.

The photodetector according to one aspect of the present disclosure may be [8] “the photodetector according to any one of [1] to [7], wherein, in the avalanche photodiode, a trench for reflecting the light diffracted by the plasmonic structure portion is formed so as to surround the first semiconductor region when viewed from a direction perpendicular to the light incidence surface”. In this case, by reflecting the light using the trench, it is possible to further increase the optical path length in the first semiconductor region.

The photodetector according to one aspect of the present disclosure may be [9] “the photodetector according to any one of [1] to [8], wherein, when viewed from a direction perpendicular to the light incidence surface, the plurality of unit structures are arranged along a first direction, and each of the plurality of unit structures has a shape elongated in a second direction perpendicular to the first direction”. In this case, for example, one of the P-polarized light and the S-polarized light can be diffracted by the plasmonic structure portion, while the other light can be reflected by the plasmonic structure portion.

The photodetector according to one aspect of the present disclosure may be [10] “the photodetector according to [1] or [2], wherein the plasmonic structure portion is configured so that second-order diffracted light travels at an angle of 70° or more and less than 90° with respect to a direction perpendicular to the light incidence surface”. In this case, size the size of the plasmonic structure portion can be secured, it is possible to secure the manufacturing accuracy.

The photodetector according to one aspect of the present disclosure may be [11] “the photodetector according to [1] or [2], wherein the plasmonic structure portion is covered with a protective layer, and the protective layer is inserted between the unit structures adjacent to each other”. In this case, it is possible to increase the physical and chemical durability of the plasmonic structure portion and to further provide a predetermined optical element on the protective layer.

The photodetector according to one aspect of the present disclosure may be [12] “the photodetector according to [6], wherein the silicon dioxide layer has a thickness of 1 nm or more and 5 nm or less”. In this case, the above-described function and effect that the surface plasmon resonance can occur in a desired wavelength range by adjusting the thickness of silicon dioxide layer are noticeably achieved.

The photodetector according to one aspect of the present disclosure may be [13] “the photodetector according to [7], wherein the adhesion layer is a titanium layer”. In this case, the light absorption rate can be improved.

According to one aspect of the present disclosure, it is possible to provide a photodetector capable of improving quantum efficiency.

### BRIEF DESCRIPTION OF THE DRAWINGS

FIG. 1A is a plan view of a photodetector, and FIG. 1B is a cross-sectional view taken along the line BB in FIG. 1A.

FIG. 2A is a perspective view of a unit structure, and FIG. 2B is a photograph showing the unit structure.

FIG. 3 is a cross-sectional view of a unit structure of a first example.

FIG. 4 is a cross-sectional view of a unit structure of a second example.

FIG. 5A is a cross-sectional view of a PonN-type structure, and FIG. 5B is a cross-sectional view of an NonP-type structure.

FIG. 6A is a cross-sectional view of a structure in which a plasmonic structure portion is arranged in a PonN type, and FIG. 6B is a diagram showing an electric field mode in the structure of FIG. 6A.

FIGS. 7A to 11B are graphs showing the relationships between the wavelength and the absorption (absorptance), the transmittance, and the reflectivity (reflectance) when a period P is 520 nm in the first example.

FIG. 7A is a graph when the height H is 50 nm, and FIG. 7B is a graph when the height H is 60 nm.

FIG. 8A is a graph when the height H is 70 nm, and FIG. 8B is a graph when the height H is 80 nm.

FIG. 9A is a graph when the height H is 90 nm, and FIG. 9B is a graph when the height H is 100 nm.

FIG. 10A is a graph when the height H is 125 nm, and FIG. 10B is a graph when the height H is 150 nm.

FIG. 11A is a graph when the height H is 175 nm, and FIG. 11B is a graph when the height H is 200 nm.

FIGS. 12A to 14 are graphs showing the relationships between the wavelength and the absorption, the transmittance, and the reflectivity when the period P is 250 nm in the first example. FIG. 12A is a graph when the height H is 100 nm, and FIG. 12B is a graph when the height H is 125 nm.

FIG. 13A is a graph when the height H is 150 nm, and FIG. 13B is a graph when the height H is 175 nm.

FIG. 14 is a graph when the height H is 200 nm.

FIGS. 15A to 17 are graphs showing the relationships between the wavelength and the absorption, the transmittance, and the reflectivity when the period P is 260 nm in the first example. FIG. 15A is a graph when the height H is 100 nm, and FIG. 15B is a graph when the height H is 125 nm.

FIG. 16A is a graph when the height H is 150 nm, and FIG. 16B is a graph when the height H is 175 nm.

FIG. 17 is a graph when the height H is 200 nm.

FIGS. 18A to 25 are graphs showing the relationships between the wavelength and the absorption, the transmittance, and the reflectivity when the angle θ is 80.5° and the period P is 520 nm in the second example. FIGS. 18A to 22B are graphs when the gap is 20 nm to 60 nm, and FIGS. 23A to 25 are graphs when the gap is 70 nm to 130 nm. FIG. 18A is a graph when the height H is 100 nm, and FIG. 18B is a graph when the height H is 125 nm.

FIG. 19A is a graph when the height H is 150 nm, and FIG. 19B is a graph when the height H is 175 nm.

FIG. 20A is a graph when the height H is 200 nm, and FIG. 20B is a graph when the height H is 210 nm.

FIG. 21A is a graph when the height H is 220 nm, and FIG. 21B is a graph when the height H is 230 nm.

FIG. 22A is a graph when the height H is 240 nm, and FIG. 22B is a graph when the height H is 250 nm.

FIG. 23A is a graph when the height H is 100 nm, and FIG. 23B is a graph when the height H is 125 nm.

FIG. 24A is a graph when the height H is 150 nm, and FIG. 24B is a graph when the height H is 175 nm.

FIG. 25 is a graph when the height H is 200 nm.

FIGS. 26A to 32 are graphs showing the relationships between the wavelength and the absorption, the transmittance, and the reflectivity when the angle θ is 77.5° and the period P is 520 nm in the second example. FIGS. 26A to 29 are graphs when the gap is 20 nm to 60 nm, and FIGS. 30A to 32 are graphs when the gap is 70 nm to 130 nm. FIG. 26A is a graph when the height H is 100 nm, and FIG. 26B is a graph when the height H is 125 nm.

FIG. 27A is a graph when the height H is 150 nm, and FIG. 27B is a graph when the height H is 175 nm.

FIG. 28A is a graph when the height H is 200 nm, and FIG. 28B is a graph when the height H is 225 nm.

FIG. 29 is a graph when the height H is 250 nm.

FIG. 30A is a graph when the height H is 100 nm, and FIG. 30B is a graph when the height H is 125 nm.

FIG. 31A is a graph when the height H is 150 nm, and FIG. 31B is a graph when the height H is 175 nm.

FIG. 32 is a graph when the height H is 200 nm.

FIGS. 33A to 35 are graphs showing the relationships between the wavelength and the absorption, the transmittance, and the reflectivity when the angle θ is 77.5° and the period P is 250 nm in the second example. FIG. 33A is a graph when the height H is 100 nm, and FIG. 33B is a graph when the height H is 125 nm.

FIG. 34A is a graph when the height H is 150 nm, and FIG. 34B is a graph when the height H is 175 nm.

FIG. 35 is a graph when the height H is 200 nm.

FIGS. 36A to 38 are graphs showing the relationships between the wavelength and the absorption, the transmittance, and the reflectivity when the angle θ is 77.5° and the period P is 260 nm in the second example. FIG. 36A is a graph when the height H is 100 nm, and FIG. 36B is a graph when the height H is 125 nm.

FIG. 37A is a graph when the height H is 150 nm, and FIG. 37B is a graph when the height H is 175 nm.

FIG. 38 is a graph when the height H is 200 nm.

FIGS. 39A to 40 are graphs showing the relationship between the wavelength and the reflectivity when the angle θ is 77.5° and the period P is 520 nm in the second example. An upper graph in FIG. 39A shows calculation results when the height H is 150 nm, and a lower graph in FIG. 39A shows measurement results when the height H is 150 nm. An upper graph in FIG. 39B shows calculation results when the height H is 175 nm, and a lower graph in FIG. 39B shows measurement results when the height His 175 nm.

An upper graph in FIG. 40 shows calculation results when the height H is 200 nm, and a lower graph in FIG. 40 shows measurement results when the height H is 200 nm.

FIGS. 41A to 41C are graphs showing the relationship between the wavelength and the enhancement calculated based on the measurement results of FIGS. 39A to 40. FIGS. 41A to 41C are graphs when the height H is 150 nm, 175 nm, and 200 nm respectively.

FIGS. 42A to 44B are graphs showing the relationships between the wavelength and the absorption, the transmittance, and the reflectivity when the presence or absence of a silicon dioxide layer and its thickness are changed when the angle θ is 77.5° and the period P is 520 nm in the second example. FIG. 42A is a graph when there is no silicon dioxide layer, and FIG. 42B is a graph when the thickness of the silicon dioxide layer is 1 nm.

FIG. 43A is a graph when the thickness of the silicon dioxide layer is 2 nm, and FIG. 43B is a graph when the thickness of the silicon dioxide layer is 3 nm.

FIG. 44A is a graph when the thickness of the silicon dioxide layer is 4 nm, and FIG. 44B is a graph when the thickness of the silicon dioxide layer is 5 nm.

FIGS. 45A to 46B are graphs showing the relationships between the wavelength and the absorption, the transmittance, and the reflectivity when the angle θ is 80.5°, the period P is 520 nm, and an adhesion layer formed of titanium is provided in the second example. FIG. 45A is a graph when the height H is 125 nm, and FIG. 45B is a graph when the height H is 150 nm.

FIG. 46A is a graph when the height H is 175 nm, and FIG. 46B is a graph when the height H is 200 nm.

FIG. 47A is a perspective view of a unit structure of a first modification example, and FIG. 47B is a photograph showing the unit structure of the first modification example.

FIGS. 48A and 48B are graphs when the angle θ is 77.5°, the period P is 520 nm, and the height H is 200 nm in the second example. FIG. 48A is a graph showing the relationships between the wavelength and the reflectivity and the enhancement for S-polarized light, and FIG. 48B is a graph showing the relationships between the wavelength and the reflectivity and the enhancement for P-polarized light.

FIGS. 49A and 49B are graphs when the angle θ is 77.5°, the period P is 520 nm, and the height H is 200 nm in the first modification example. FIG. 49A is a graph showing the relationships between the wavelength and the reflectivity and the enhancement for S-polarized light, and FIG. 49B is a graph showing the relationships between the wavelength and the reflectivity and the enhancement for P-polarized light.

FIG. 50A is a diagram showing an example of an electric field mode in the first example, and FIG. 50B is a diagram showing an example of an electric field mode in the second example.

An upper graph in FIG. 51A shows the relationship between the wavelength and the reflectivity when the height H is 50 nm in the first example, and a lower graph in FIG. 51A shows an electric field mode when the wavelength is 905 nm in this case. An upper graph in FIG. 51B shows the relationship between the wavelength and the reflectivity when the height H is 150 nm in the first example, and a lower graph in FIG. 51B shows an electric field mode when the wavelength is 905 nm in this case. FIGS. 51A and 51B show results for first-order diffracted light output from a plasmonic structure portion.

An upper graph in FIG. 52A shows the relationship between the wavelength and the reflectivity when the height H is 100 nm in the second example, and a lower graph in FIG. 52A shows an electric field mode when the wavelength is 905 nm in this case. An upper graph in FIG. 52B shows the relationship between the wavelength and the reflectivity when the height H is 200 nm in the second example, and a lower graph in FIG. 52B shows an electric field mode when the wavelength is 905 nm in this case. Examples of FIGS. 52A and 52B show results for first-order diffracted light output from a plasmonic structure portion.

An upper graph in FIG. 53A shows the relationship between the wavelength and the reflectivity when the height H is 50 nm in the first example, and a lower graph in FIG. 53A shows an electric field mode when the wavelength is 905 nm in this case. An upper graph in FIG. 53B shows the relationship between the wavelength and the reflectivity when the height H is 125 nm in the first example, and a lower graph in FIG. 53B shows an electric field mode when the wavelength is 905 nm in this case. Examples of FIGS. 53A and 53B show results for second-order diffracted light output from a plasmonic structure portion.

An upper graph in FIG. 54A shows the relationship between the wavelength and the reflectivity when the height H is 100 nm in the second example, and a lower graph in FIG. 54A shows an electric field mode when the wavelength is 905 nm in this case. An upper graph in FIG. 54B shows the relationship between the wavelength and the reflectivity when the height H is 200 nm in the second example, and a lower graph in FIG. 54B shows an electric field mode when the wavelength is 905 nm in this case. Examples of FIGS. 54A and 54B show results for second-order diffracted light output from a plasmonic structure portion.

FIG. 55A is a diagram for explaining localized surface plasmon resonance, FIG. 55B is a diagram for explaining propagating surface plasmon resonance, and FIG. 55C is a diagram for explaining surface lattice resonance.

FIGS. 56A and 56B correspond to FIGS. 52A and 52B, and are diagrams for explaining a difference between dipolar SLR and quadrupole SLR.

FIG. 57 is a diagram for explaining an electric field mode in the case of dipolar SLR.

FIG. 58 is a diagram for explaining an electric field mode in the case of quadrupole SLR.

FIG. 59 is a diagram for explaining an electric field mode in the case of quadrupole SLR.

FIG. 60 is a cross-sectional view of a unit structure of a second modification example.

FIGS. 61A to 62 are graphs showing the relationships between the wavelength and the absorption, the transmittance, and the reflectivity when the angle θ is 71.6° and the period P is 520 nm in the second example. FIG. 61A is a graph when the height H is 230 nm, and FIG. 61B is a graph when the height H is 240 nm.

FIG. 62 is a graph when the height H is 250 nm.

### DETAILED DESCRIPTION

Hereinafter, embodiments of the present disclosure will be described in detail with reference to the diagrams. In the following description, the same or equivalent elements are denoted by the same reference numerals, and repeated description thereof will be omitted.

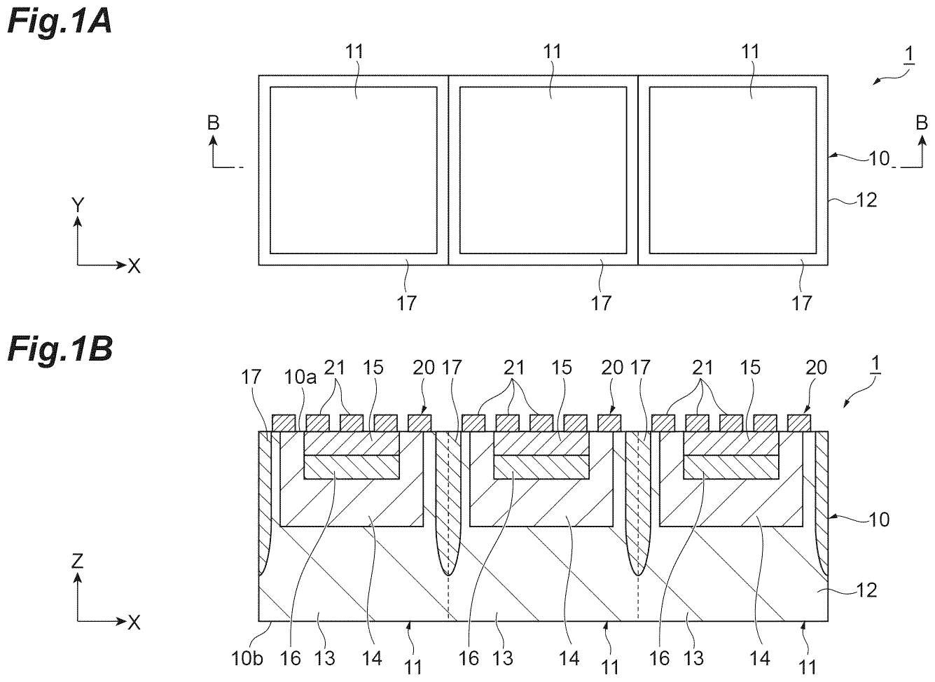

As shown in FIGS. 1A and 1B, a photodetector 1 includes an avalanche photodiode (hereinafter, also referred to as an “APD”) 10. The APD 10 has a light incidence surface 10a on which light L is incident and a surface 10b on a side opposite to the light incidence surface 10a. The light incidence surface 10a and the surface 10b are, for example, flat surfaces parallel to each other. The APD 10 is a photodiode that utilizes avalanche multiplication, and absorbs the light L and converts the light L into a photocurrent. In the APD 10, the photocurrent is multiplied by application of a reverse voltage. The photodetector 1 has sensitivity to light in the near-infrared range (for example, 750 nm to 2.5 μm).

The APD 10 has a plurality of pixel portions 11. In the example of FIGS. 1A and 1B, three pixel portions 11 are arranged in an X direction (first direction). The plurality of pixel portions 11 may be arranged in a lattice (matrix) pattern, or may be aligned along each of the X direction and a Y direction (direction perpendicular to the X direction) (second direction), for example. The number of pixel portions 11 is not limited. For example, only one pixel portion 11 may be provided, or four or more pixel portions 11 may be provided.

Each pixel portion 11 is formed, for example, in a rectangular shape in plan view (when viewed from a Z direction). The Z direction is a direction perpendicular to the X and Y directions, and a direction perpendicular to the light incidence surface 10a. Each pixel portion 11 is formed on a semiconductor substrate 12 formed of, for example, silicon (Si). Each pixel portion 11 has an n-type semiconductor region 13, an n-type semiconductor region 14, a p-type semiconductor region 15 (first semiconductor region), and an n-type semiconductor region 16 (second semiconductor region). The semiconductor regions 15 and 16 function as avalanche multiplication regions for generating avalanche multiplication.

The n-type semiconductor region 13 is, for example, a substrate region. The semiconductor region 13 forms the surface 10b of the APD 10. The n-type semiconductor region 14 is, for example, an epitaxial region (epitaxial layer), and has a lower impurity concentration than the semiconductor region 13. The semiconductor region 14 functions as a sensitivity region (light absorption region) having sensitivity to the light L together with the semiconductor regions 15 and 16. A part of the semiconductor region 14 is exposed to the light incidence surface 10a.

The p-type semiconductor region 15 and the n-type semiconductor region 16 are regions (layers) where the impurity concentration is increased by ion implantation, for example. The n-type semiconductor region 16 has an impurity concentration higher than the semiconductor region 14 and lower than the semiconductor region 13. The impurity concentrations of the semiconductor regions 15 and 16 are set to values that can generate avalanche multiplication. The semiconductor region 15 is arranged on the light incidence surface 10a side so as to be exposed to the light incidence surface 10a. The semiconductor region 16 is formed on a side of the semiconductor region 15 opposite to the light incidence surface 10a, forming a pn junction with the semiconductor region 15. A part of the semiconductor region 14 is located on a side of the semiconductor regions 15 and 16 opposite to the light incidence surface 10a. In plan view, the semiconductor regions 15 and 16 are surrounded by the semiconductor region 14.

A trench 17 is formed around the entire outer edge of each pixel portion 11. The trench 17 surrounds the semiconductor region 15 when viewed in the Z direction. The trench 17 is formed so as to extend in the Z direction from the light incidence surface 10a. The trench 17 functions as a low sensitivity region having no sensitivity (or having low sensitivity) to the light L. The trench 17 is formed, for example, by filling a groove formed in the light incidence surface 10a with a metal material.

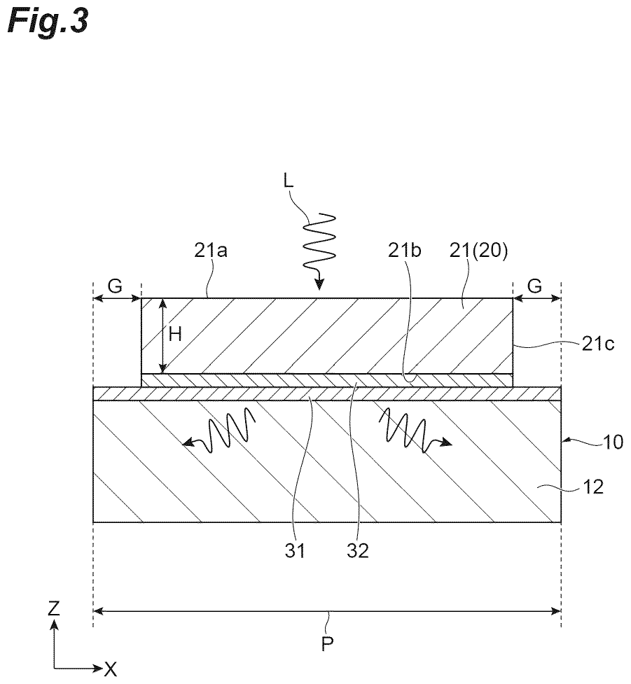

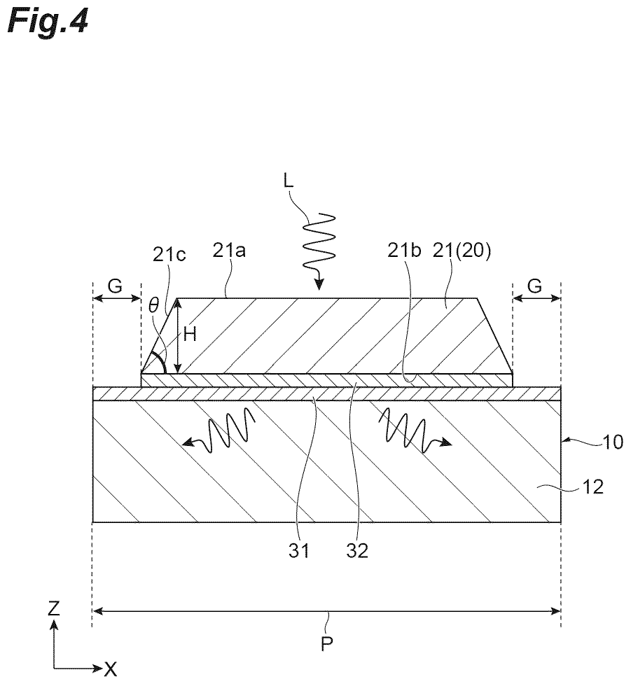

As shown in FIGS. 1A to 4, the photodetector 1 further includes a plasmonic structure portion 20 formed on the light incidence surface 10a. As shown in FIGS. 3 and 4, the plasmonic structure portion 20 diffracts the light L by surface plasmon resonance, and causes the diffracted light to travel in a direction crossing the Z direction. The angle of the travel direction of the diffracted light with respect to the Z direction is, for example, 80°. The surface plasmon resonance will be described in detail later.

The plasmonic structure portion 20 has a plurality of unit structures 21 arranged on the light incidence surface 10a (semiconductor region 15) of the APD 10. The unit structures 21 are arranged, for example, in a lattice (matrix) pattern, and are aligned along each of the X and Y directions. In this example, the unit structure 21 is formed in a square shape in plan view. The unit structure 21 is formed of, for example, a metal material, a dielectric material, or a semiconductor material (for example, silicon). Examples of the dielectric material forming the unit structure 21 include TiO₂, SiO₂, HfO₂, SiN, and a-Si. In this example, the unit structure 21 is formed of gold (Au), which is a metal material. Other examples of the metal material forming the unit structure 21 include silver (Ag) and aluminum (Al). Although the unit structure 21 is shown in a simplified form in FIG. 1B, in reality, a larger number of small unit structures 21 than those shown in FIG. 1B are arranged side by side in practice.

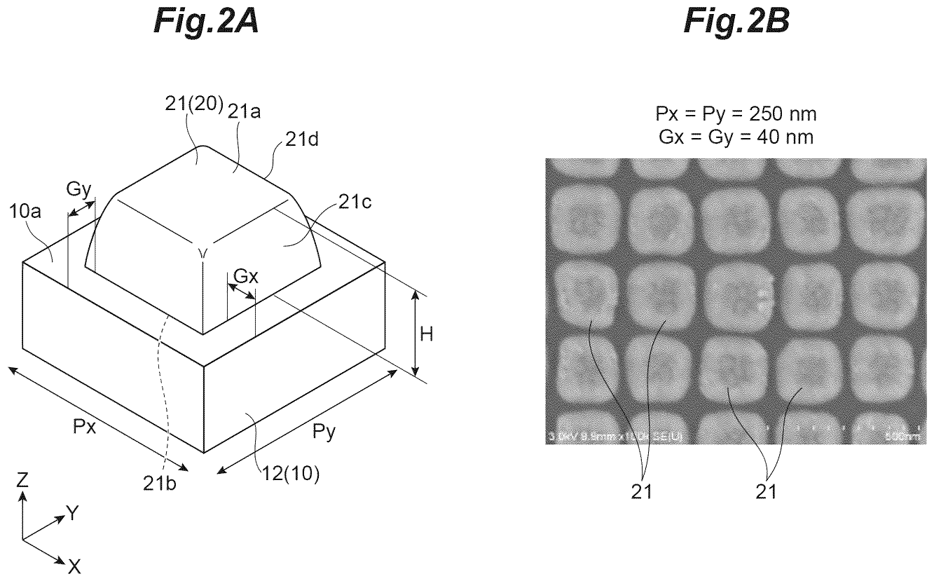

The unit structure 21 has a shape of a first example shown in FIG. 3 or a second example shown in FIG. 4, for example. The unit structure 21 of the first example includes a top surface 21a on a side opposite to the light incidence surface 10a, a bottom surface 21b facing the light incidence surface 10a, and a side surface 21c connected to the top surface 21a and the bottom surface 21b. The top surface 21a and the bottom surface 21b are, for example, flat surfaces parallel to the light incidence surface 10a. The side surface 21c is a flat surface perpendicular to the light incidence surface 10a. That is, the unit structure 21 of the first example is formed to have an approximately rectangular shape in a cross section perpendicular to the X direction and a cross section perpendicular to the Y direction. The boundary between the top surface 21a and the side surface 21c (the edge of the top surface 21a) is rounded in an R shape over the entire circumference so that there are no sharp corners (FIG. 2A). That is, the top surface 21a and the side surface 21c are connected to each other via a curved surface 21d. The curved surface 21d is curved, for example, in an arc shape in a cross section perpendicular to the X direction and a cross section perpendicular to the Y direction.

The unit structure 21 of the second example shown in FIG. 4 is different from the unit structure 21 of the first example in that the side surface 21c is inclined (formed in a tapered shape). In the second example, the side surface 21c is inclined so as to widen toward the bottom surface 21b. That is, the unit structure 21 of the second example is formed in a trapezoidal shape in a cross section perpendicular to the X direction and a cross section perpendicular to the Y direction. The angle θ of the side surface 21c with respect to the bottom surface 21b is, for example, 50° or more and less than 90°.

Hereinafter, as shown in FIG. 2A, it is assumed that the arrangement period of the unit structures 21 in the X direction is Px, the arrangement period of the unit structures 21 in the Y direction is Py, the distance between the unit structures 21 adjacent to each other in the X direction is Gx, the distance between the unit structures 21 adjacent to each other in the Y direction is Gy, and the height of the unit structure 21 is H. The period Px is a length obtained by adding 2×Gx to the width of the unit structure 21 in the X direction, and the period Py is a length obtained by adding 2×Gy to the width of the unit structure 21 in the Y direction. The height H is 100 nm or more and 250 nm or less. FIG. 2B is a photograph of the unit structure 21 when Px and Py are 250 nm and Gx and Gy are 40 nm.

As shown in FIGS. 3 and 4, the photodetector 1 further includes a silicon dioxide (SiO₂) layer 31 formed between the plasmonic structure portion 20 and the light incidence surface 10a (semiconductor region 15) and an adhesion layer 32 formed between the plasmonic structure portion 20 and the silicon dioxide layer 31. That is, in this example, the plasmonic structure portion 20 is formed on the light incidence surface 10a with the silicon dioxide layer 31 and the adhesion layer 32 interposed therebetween. The silicon dioxide layer 31 has a thickness of, for example, 1 nm to 5 nm. The adhesion layer 32 is formed of a metal material. In this example, the adhesion layer 32 is formed of titanium (Ti). Another example of the metal material forming the adhesion layer 32 is chromium (Cr). The adhesion layer 32 has a thickness of, for example, about 3 nm.

Although not shown, the photodetector 1 has a pair of electrodes for applying a voltage to the APD 10, for example, on the light incidence surface 10a side and the surface 10b side. A reverse voltage is applied to the photodetector 1 through the electrodes. The APD 10 operates, for example, in the Geiger mode. In this case, a reverse voltage equal to or greater than the breakdown voltage is applied. The APD 10 may operate in a linear mode. In this case, a reverse voltage less than the breakdown voltage is applied. In addition, the photodetector 1 may further include a lens for focusing the light L onto a sensitivity region of the APD 10.

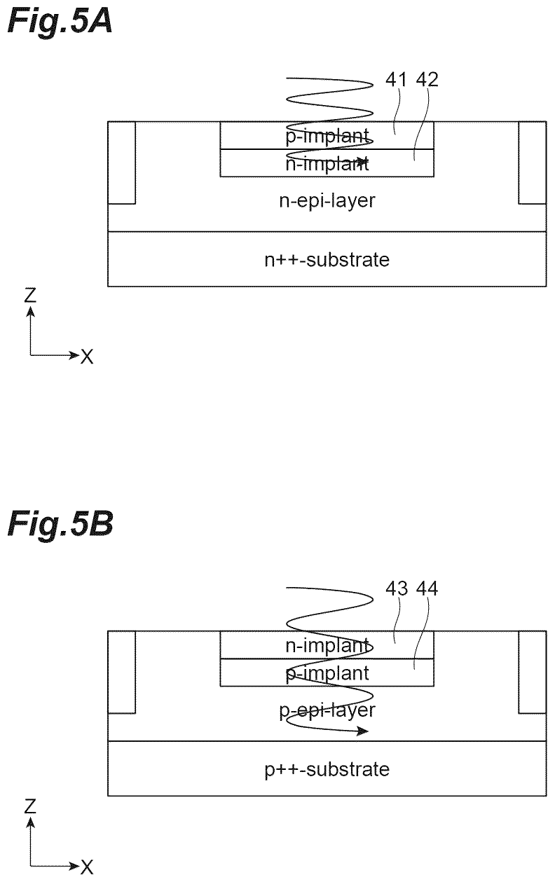

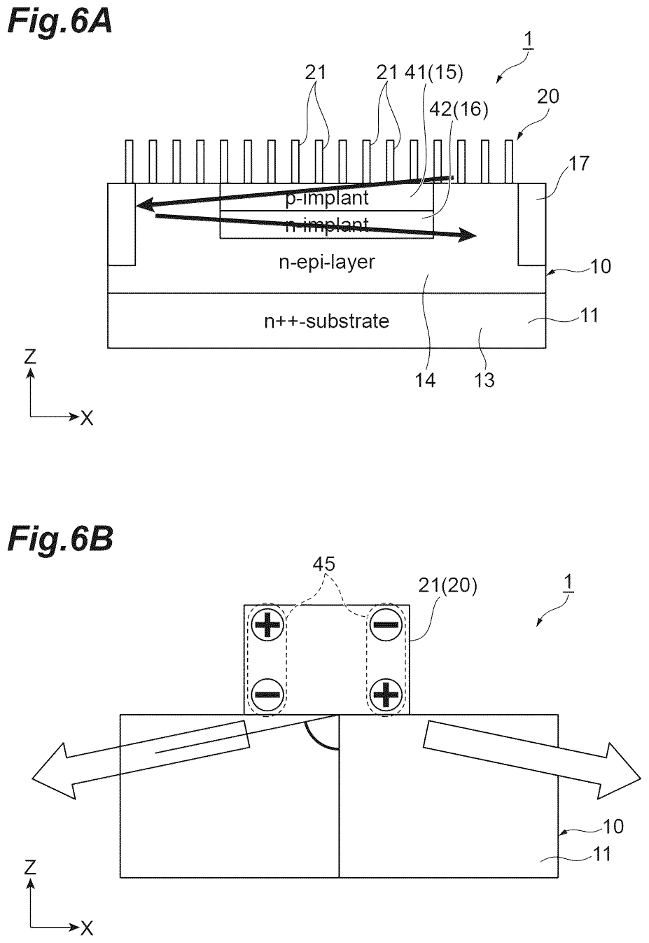

The photodetector 1 will be described with reference to FIGS. 5A to 6B. As the avalanche photodiode, a PonN-type structure shown in FIG. 5A and an NonP-type structure shown in FIG. 5B are considered. As shown in FIG. 5A, in the PonN-type structure, a p-type semiconductor layer 41 is formed on an n-type semiconductor layer 42 and is located on the light incidence surface side. As shown in FIG. 5B, in the NonP-type structure, an n-type semiconductor layer 43 is formed on an n-type semiconductor layer 44 and is located on the light incidence surface side. The above-described photodetector 1 is of a PonN type.

In avalanche photodiodes, a p-layer is used as a light absorption layer. For example, when configuring an avalanche photodiode so as to have sensitivity to light in the visible or near ultraviolet range, a PonN type can be adopted. This is because the light absorption layer as a p-layer easily absorbs light in these wavelength ranges and accordingly, the p-type semiconductor layer 41 may be thin as shown in FIG. 5A. On the other hand, when configuring an avalanche photodiode so as to have sensitivity to light in the near-infrared range, an NonP type can be adopted. This is because the light absorption layer as a p-layer has difficulty in absorbing light in the near-infrared region and it is not possible to sufficiently absorb the incident light if the p-type semiconductor layer 41 is thin as in the case of the PonN type, and accordingly, it is necessary to absorb light by using the p-type semiconductor layer on the substrate side as well as shown in FIG. 5B.

In this regard, the photodetector 1 according to the embodiment has sensitivity to light in the near-infrared range, but is configured as a PonN type. This is because, as shown in FIG. 6A, the provision of the plasmonic structure portion 20 makes it possible to diffract light by surface plasmon resonance and cause the diffracted light to travel in a direction crossing the Z direction, and accordingly, it is possible to increase the amount of light absorption by increasing the optical path length in the p-type semiconductor layer 41 (semiconductor region 15). By adopting the PonN type when the photodetector 1 according to the embodiment has sensitivity to light in the near-infrared range as described above, it is possible to improve the time resolution and sensitivity. The time resolution can be improved because the excitation point can be limited to a thin layer (p-layer) near the surface by focusing the diffracted light of the plasmonic structure near the surface, and accordingly, it is possible to suppress fluctuations in the time it takes for excited electrons to reach avalanche multiplication. In addition, in the photodetector 1, since the trench 17 is provided so as to surround the sensitivity region, the optical path length in the p-type semiconductor layer 41 can be further increased by reflecting the diffracted light from the plasmonic structure portion 20 using the trench 17.

As shown in FIG. 6B, in the photodetector 1, localized surface plasmon resonance occurs in the plasmonic structure portion 20. In the localized surface plasmon resonance, an electric field mode is formed such that a dipole 45 formed by a pair of positive and negative poles extends along the Z direction. As a result, the light L is diffracted so as to travel in a direction crossing the Z direction. On the other hand, the present inventors have found that in order to generate localized surface plasmon resonance in the plasmonic structure portion 20, it is necessary to devise the structure of the plasmonic structure portion 20. Hereinafter, explanation on this point will be given.

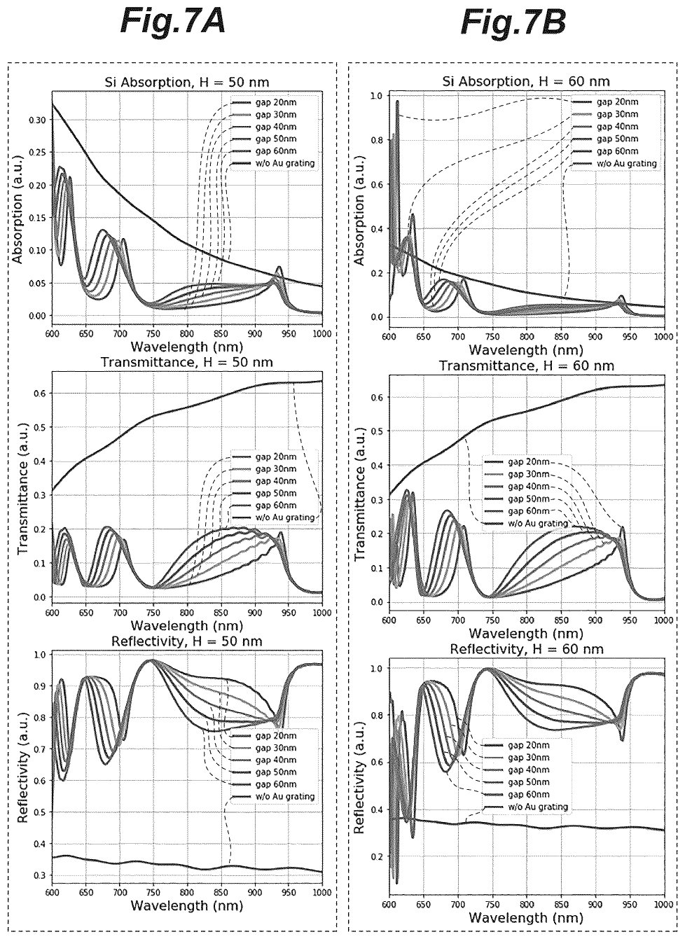

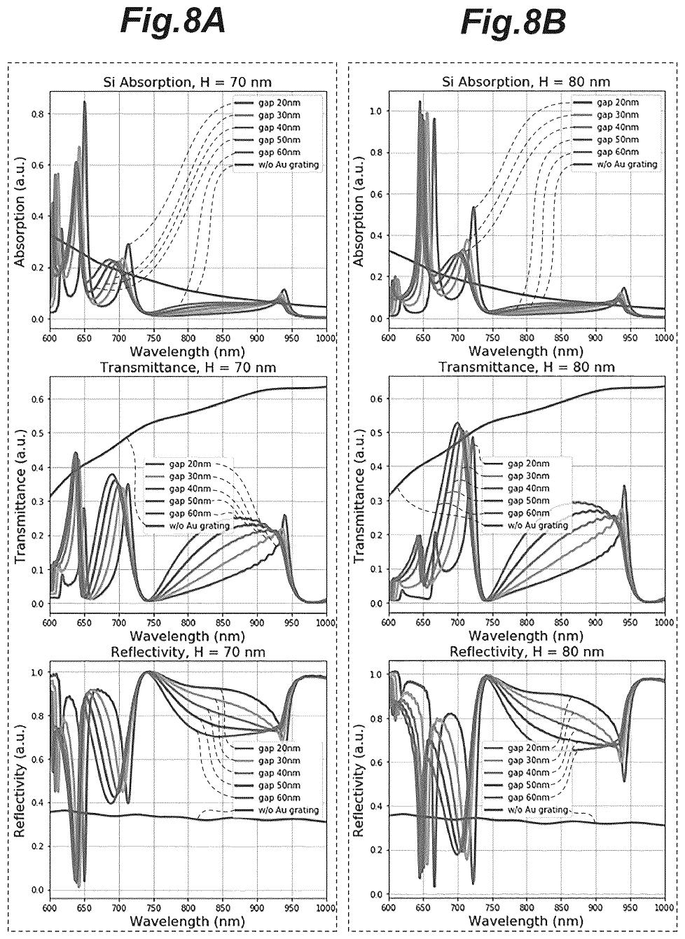

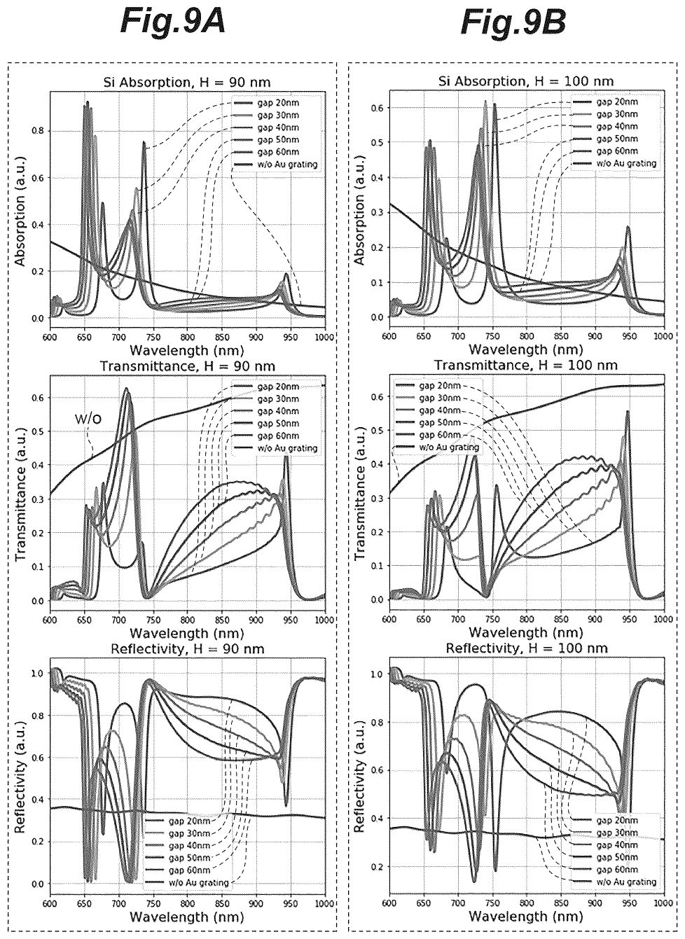

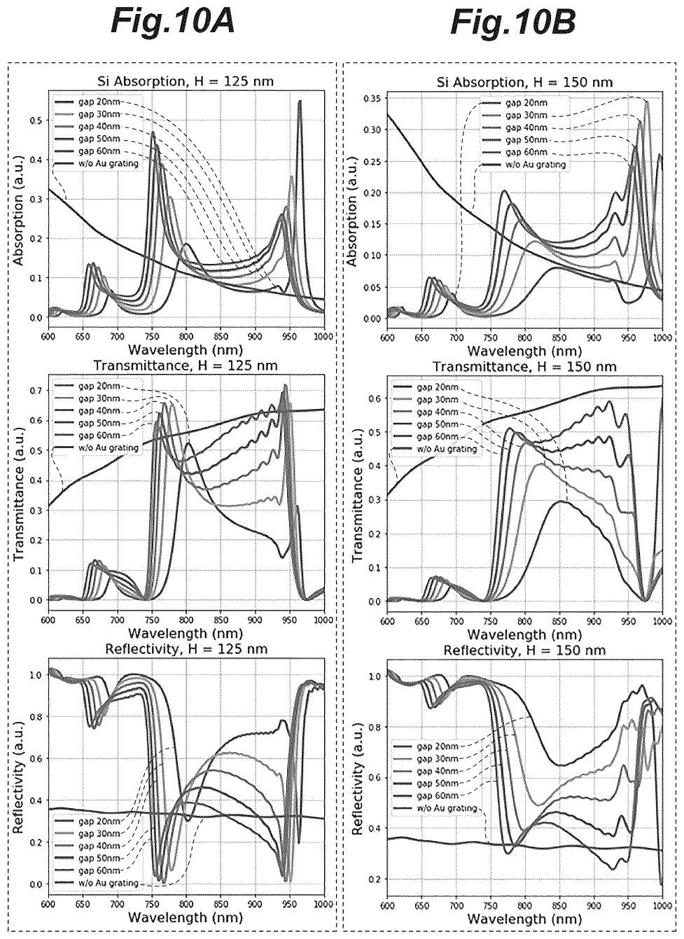

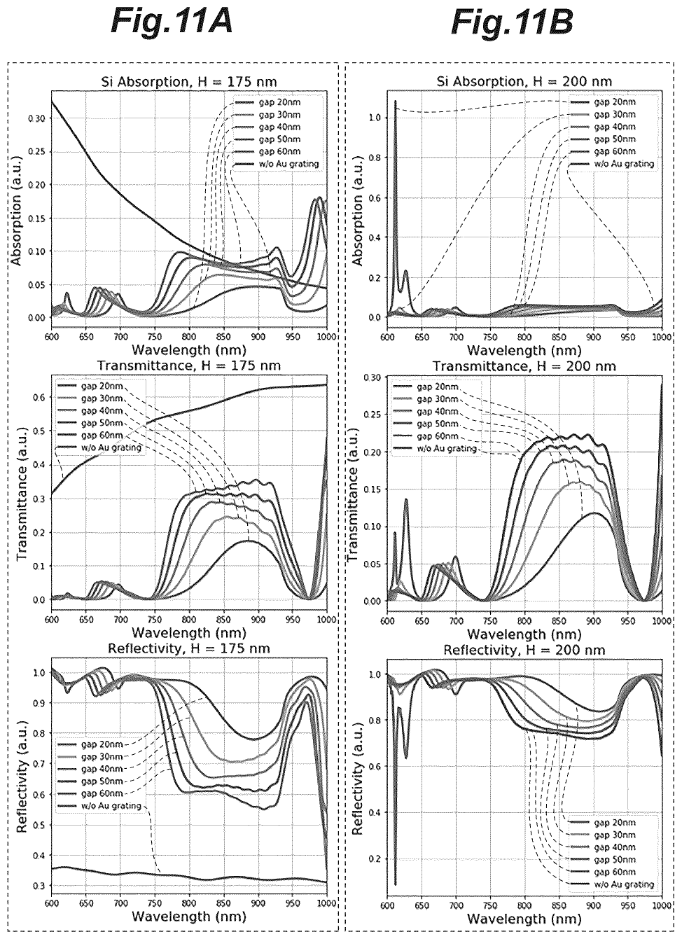

FIGS. 7A to 11B are graphs showing the relationships between the wavelength and the absorption (absorptance), the transmittance, and the reflectivity (reflectance) when the period P (Px and Py described above) is 520 nm in the first example (where the side surface 21c is vertical) shown in FIG. 3. The absorption, transmittance, and reflectivity in each graph are the absorption, transmittance, and reflectivity in the APD 10. Each graph shows the results of a simulation using a finite difference time domain method (FDTD method). FIGS. 7A, 7B, 8A, 8B, 9A, 9B, 10A, 10B, 11A, and 11B are graphs when the height H is 50 nm, 60 nm, 70 nm, 80 nm, 90 nm, 100 nm, 125 nm, 150 nm, 175 nm, and 200 nm, respectively. The graphs show the results when the gap (Gx and Gy described above) is 20 nm, 30 nm, 40 nm, 50 nm, and 60 nm. In addition, a result when the plasmonic structure portion 20 is not provided is shown as “w/o Au grating”. In this simulation, the thickness of the silicon dioxide layer 31 was set to 3 nm. The adhesion layer 32 was not provided. The plasmonic structure portion 20 was configured so that the second-order diffracted light traveled at an angle of 70° or more and less than 90° with respect to the Z direction (direction perpendicular to the light incidence surface 10a). In each diagram, results for the second-order diffracted light output from the plasmonic structure portion 20 are shown.

In each diagram, for example, when the reflectivity at the target wavelength (750 nm or more in this example) is lower than that in a case where the plasmonic structure portion 20 is not provided, it can be understood that reflection can be suppressed by providing the plasmonic structure portion 20 and accordingly, localized surface plasmon resonance can occur in the plasmonic structure portion 20.

From FIGS. 7A to 11B, it can be seen that when the height H is in the range of 100 nm to 150 nm, the reflectivity at the target wavelength is lower than that in a case where the plasmonic structure portion 20 is not provided and accordingly, localized surface plasmon resonance can occur in the plasmonic structure portion 20. In particular, it can be seen that when the height H is in the range of 100 nm to 125 nm, the wavelength range in which the reflectivity is reduced is narrow and accordingly, localized surface plasmon resonance can occur in a specific wavelength range.

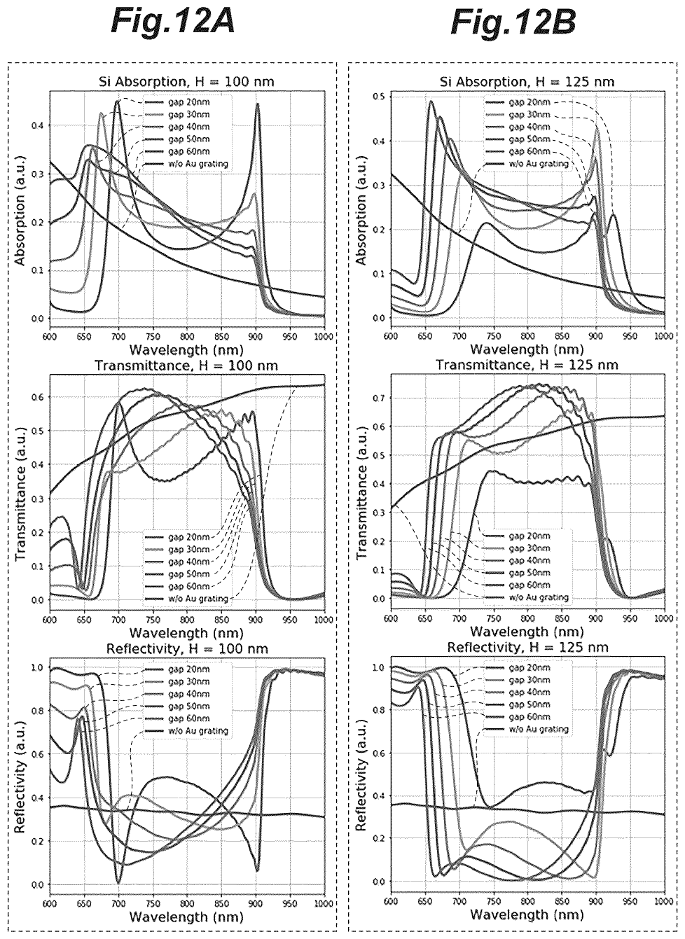

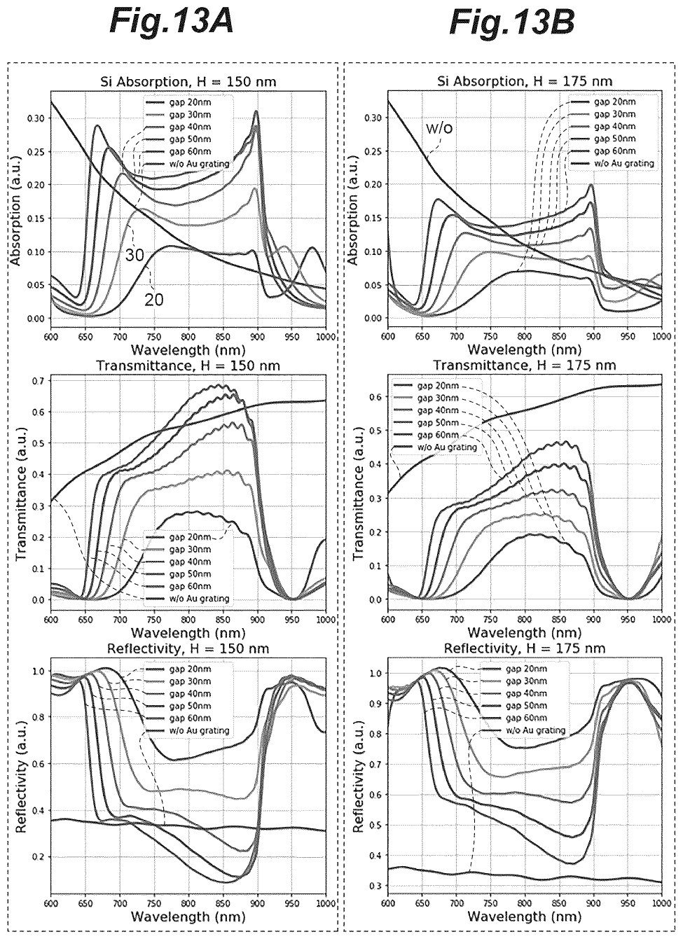

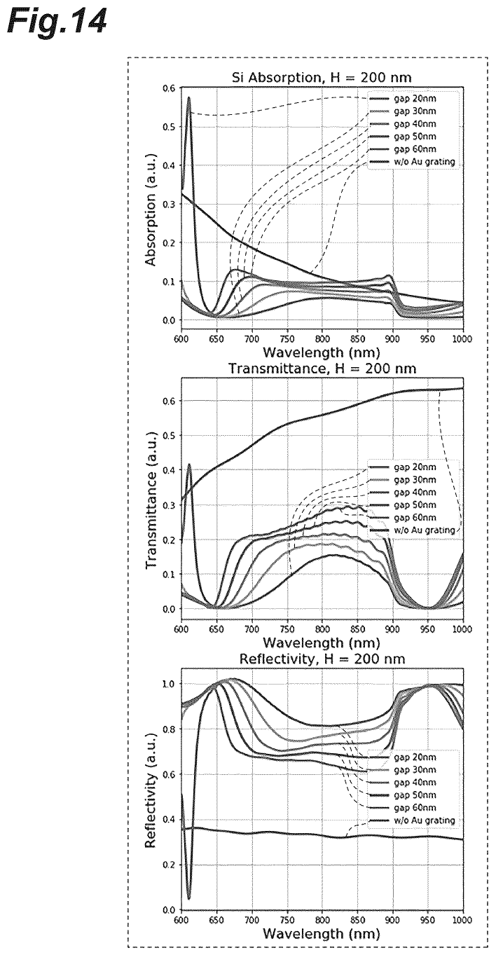

FIGS. 12A to 14 are graphs showing the relationships between the wavelength and the absorption, the transmittance, and the reflectivity when the period P is 250 nm in the first example. FIGS. 12A, 12B, 13A, 13B, and 14 are graphs when the height H is 100 nm, 125 nm, 150 nm, 175 nm, and 200 nm, respectively. Other points are the same as those in the cases of FIGS. 7A to 11B. In addition, in FIG. 13A, reference numerals “20” and “30” indicate results when the gap is 20 nm and 30 nm, respectively, and in FIG. 13B, a reference numeral “w/o” indicates a result when the plasmonic structure portion 20 is not provided. The same applies to the following diagrams.

From FIGS. 12A to 14, it can be seen that when the height H is in the range of 100 nm to 150 nm, the reflectivity at the target wavelength is lower than that in a case where the plasmonic structure portion 20 is not provided and accordingly, localized surface plasmon resonance can occur in the plasmonic structure portion 20.

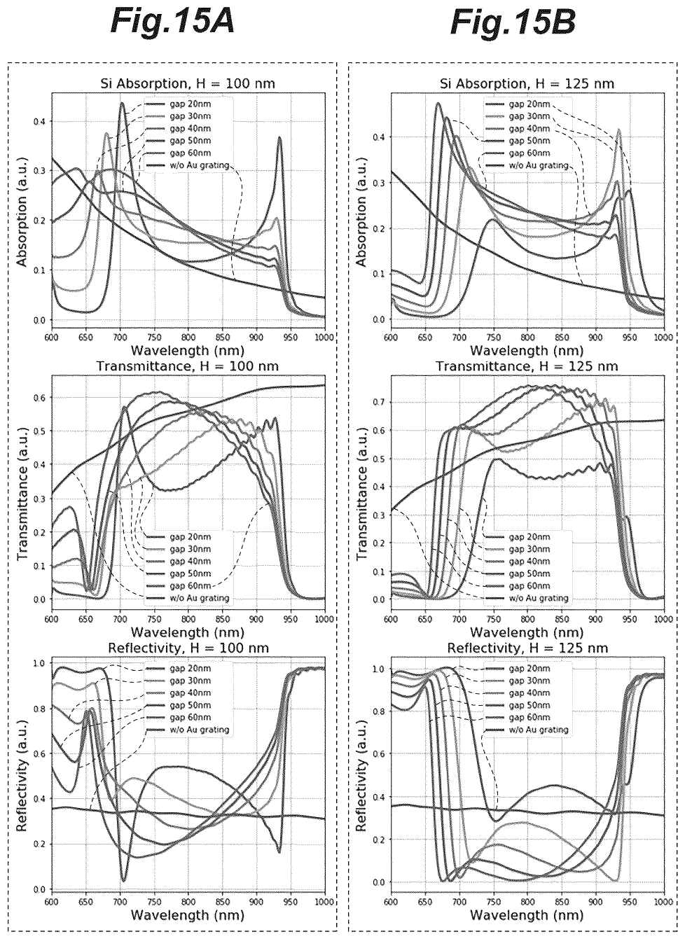

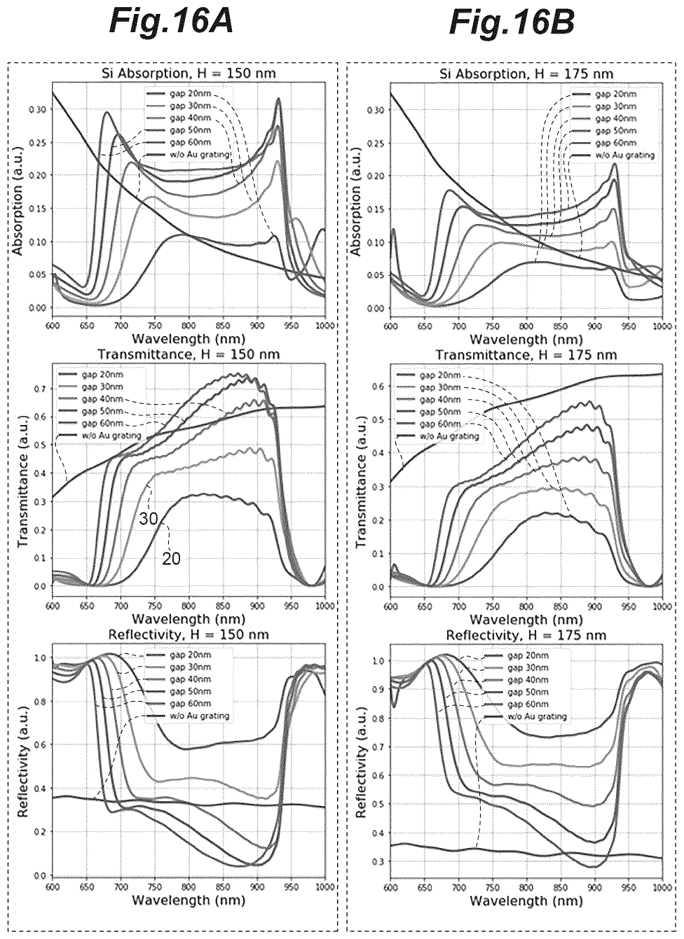

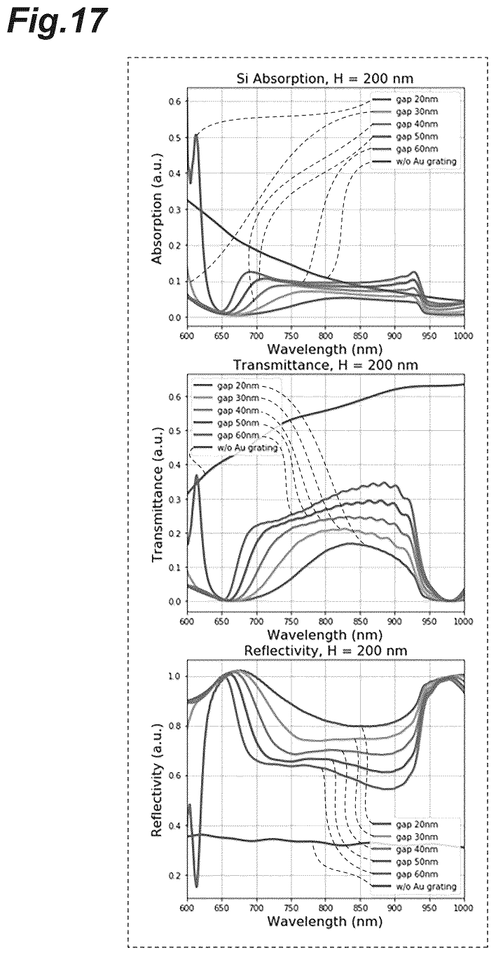

FIGS. 15A to 17 are graphs showing the relationships between the wavelength and the absorption, the transmittance, and the reflectivity when the period P is 260 nm in the first example. FIGS. 15A, 15B, 16A, 16B, and 17 are graphs when the height H is 100 nm, 125 nm, 150 nm, 175 nm, and 200 nm, respectively. Other points are the same as those in the cases of FIGS. 7A to 11B.

From FIGS. 15A to 17, it can be seen that when the height H is in the range of 100 nm to 150 nm, the reflectivity at the target wavelength is lower than that in a case where the plasmonic structure portion 20 is not provided and accordingly, localized surface plasmon resonance can occur in the plasmonic structure portion 20.

From the results in FIGS. 7A to 11B, the results in FIGS. 12A to 14, and the results in FIGS. 15A to 17, it can be seen that in the first example in which the side surface 21c is vertical, localized surface plasmon resonance can occur when the height H is in the range of 100 nm to 150 nm and accordingly, incident light can be diffracted appropriately. Although not shown, a similar calculation was also performed for the case where the period P was 500 nm in the first example, and it was confirmed that the same results were obtained.

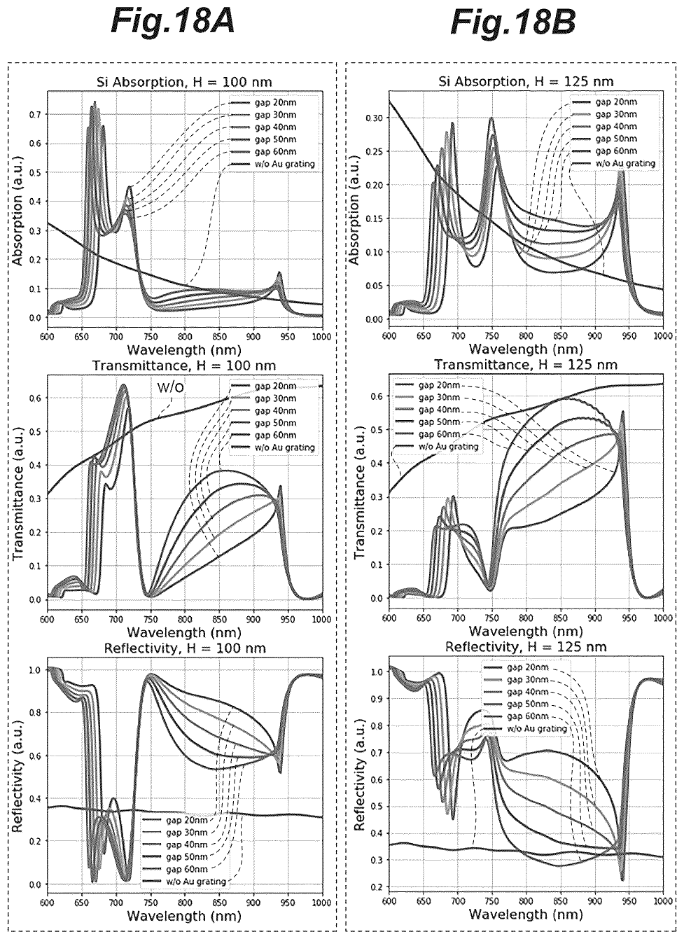

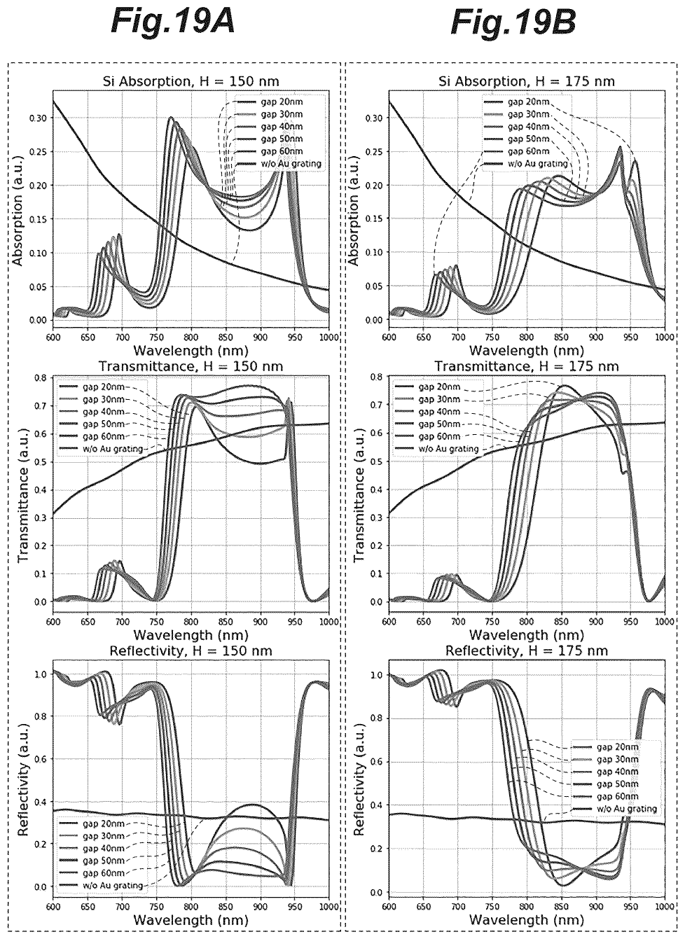

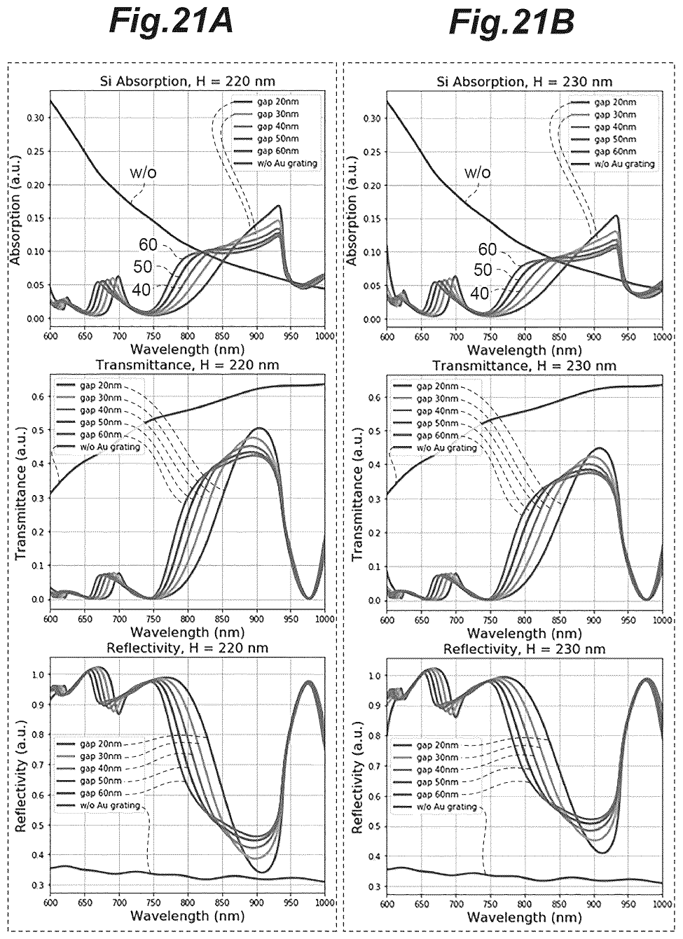

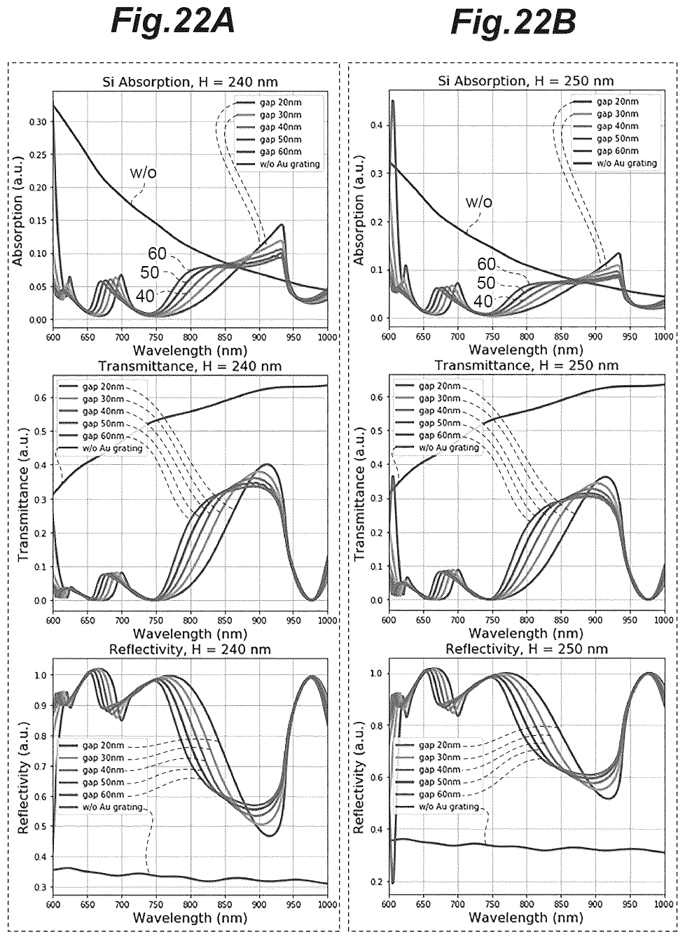

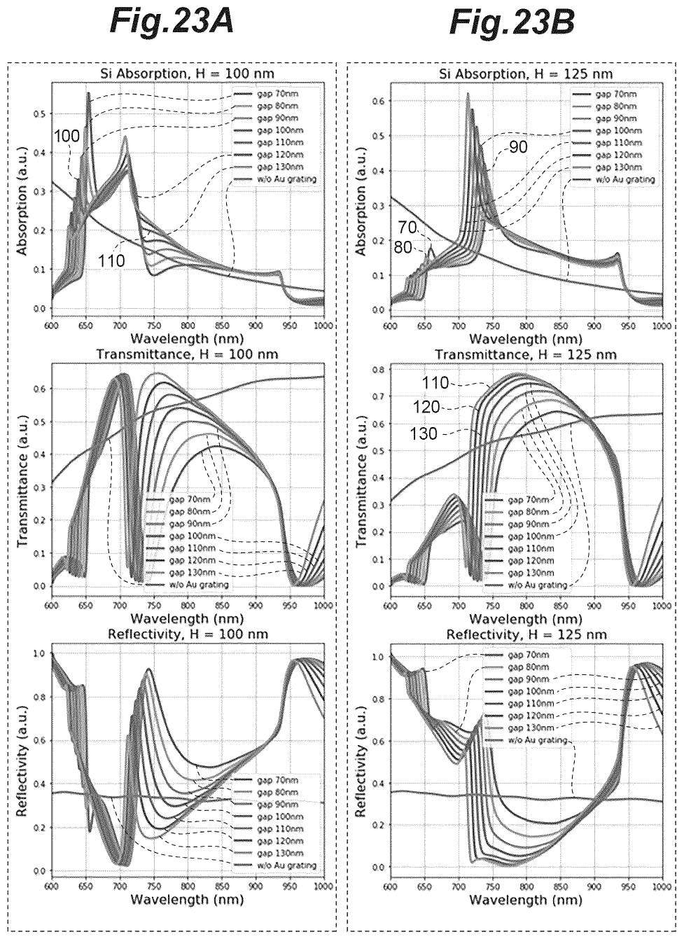

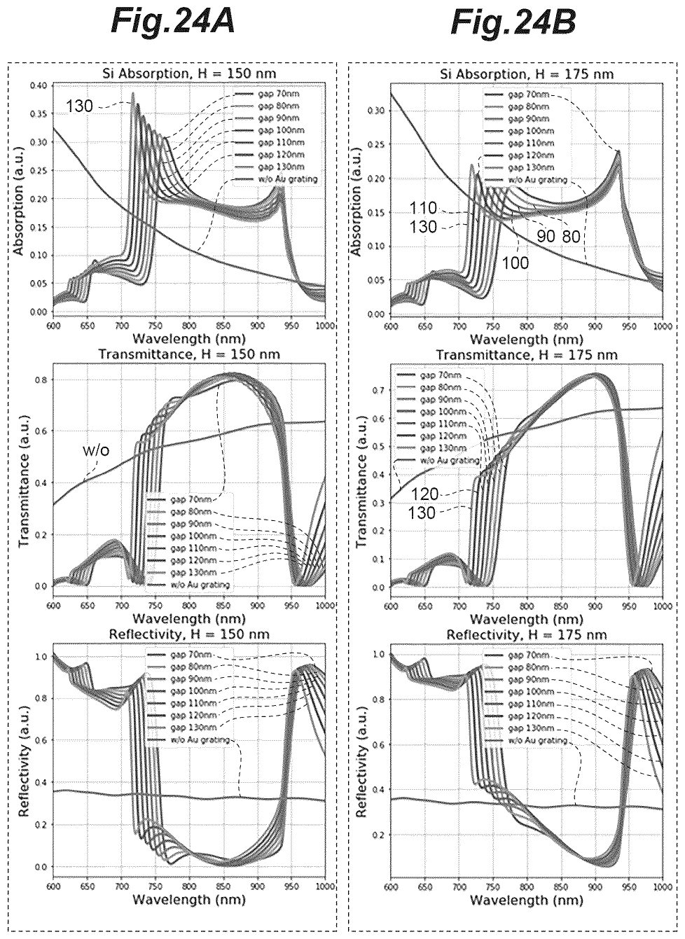

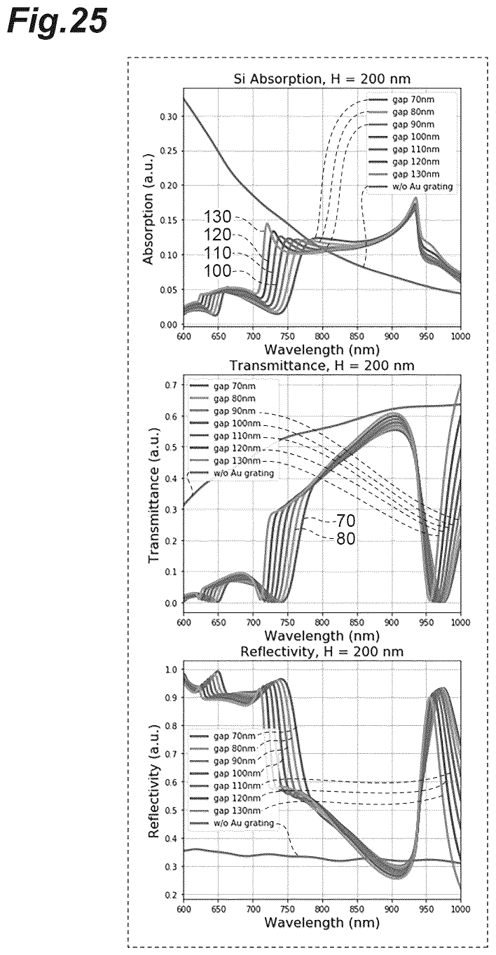

FIGS. 18A to 25 are graphs showing the relationships between the wavelength and the absorption, the transmittance, and the reflectivity when the angle θ is 80.5° (A tan (6.0)) and the period P is 520 nm in the second example (where the side surface 21c is inclined) shown in FIG. 4. FIGS. 18A to 22B are graphs when the gap is 20 nm to 60 nm, and FIGS. 23A to 25 are graphs when the gap is 70 nm to 130 nm. FIGS. 18A, 18B, 19A, 19B, 20A, 20B, 21A, 21B, 22A, and 22B are graphs when the height His 100 nm, 125 nm, 150 nm, 175 nm, 200 nm, 210 nm, 220 nm, 230 nm, 240 nm, and 250 nm, respectively. FIGS. 23A, 23B, 24A, 24B, and 25 are graphs when the height H is 100 nm, 125 nm, 150 nm, 175 nm, and 200 nm, respectively. Other points are the same as those in the cases of FIGS. 7A to 11B.

From FIGS. 18A to 25, it can be seen that when the height H is in the range of 125 nm to 210 nm, the reflectivity at the target wavelength is lower than that in a case where the plasmonic structure portion 20 is not provided and accordingly, localized surface plasmon resonance can occur in the plasmonic structure portion 20. In particular, it can be seen that when the height H is in the range of 200 nm to 210 nm, the wavelength range in which the reflectivity is reduced is narrow and accordingly, localized surface plasmon resonance can occur in a specific wavelength range. In addition, in the second example in which the side surface 21c is inclined, the wavelength range in which localized surface plasmon resonance can occur can be made wider than in the first example in which the side surface 21c is vertical.

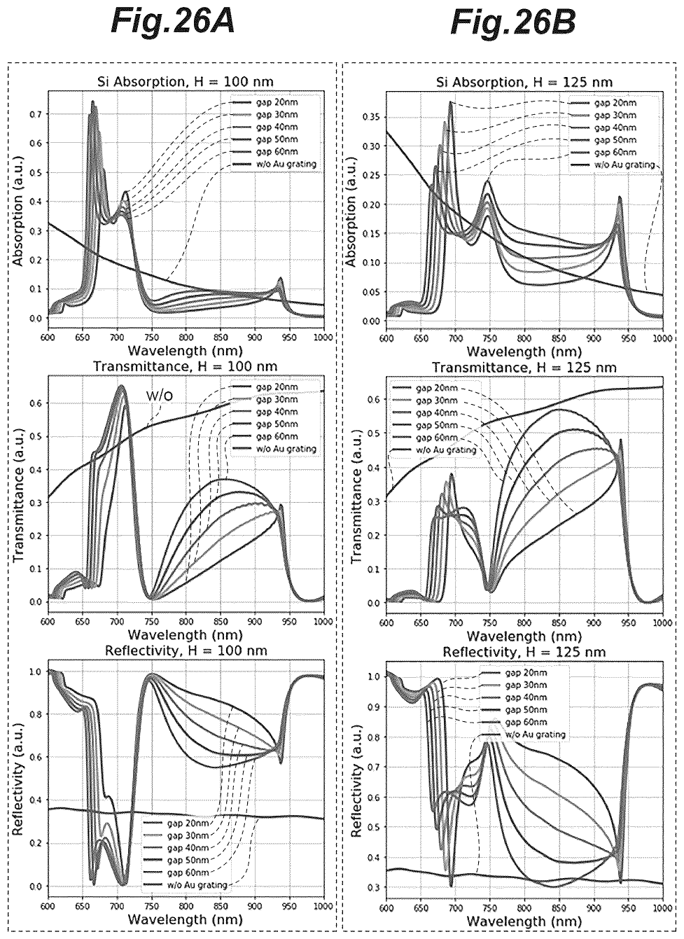

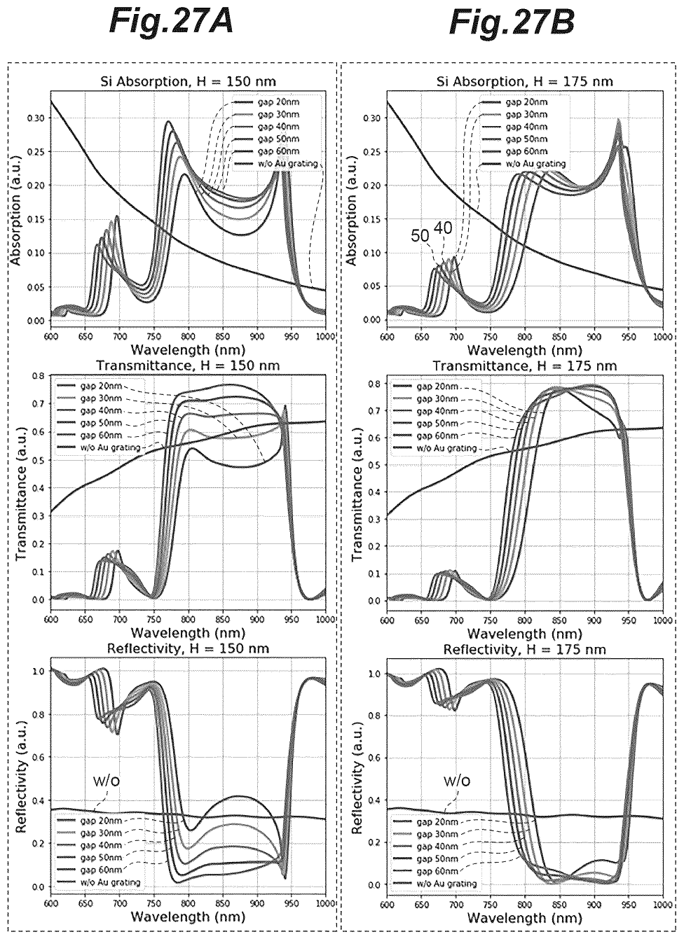

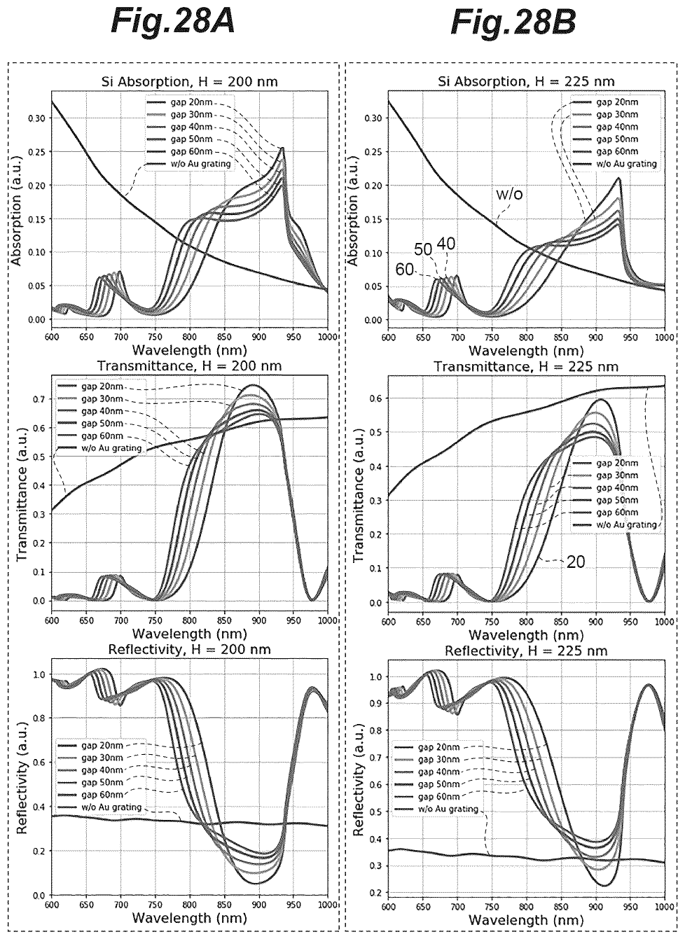

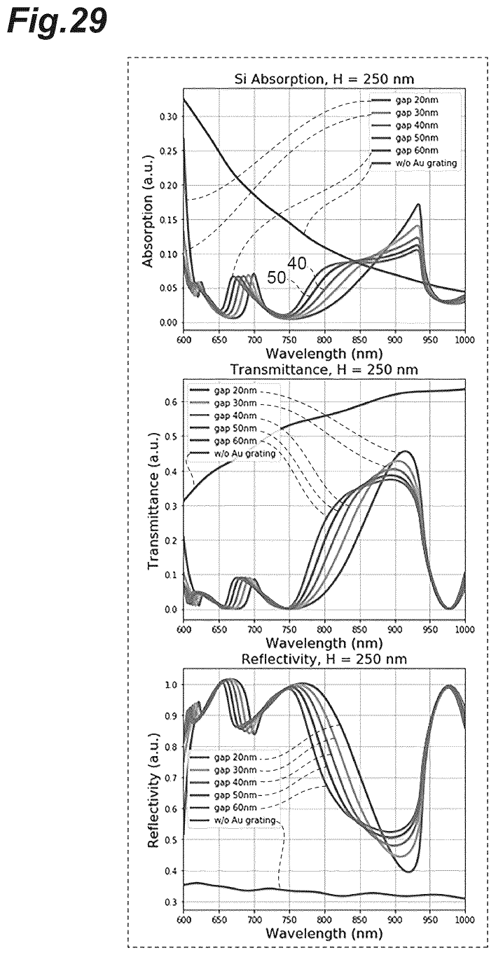

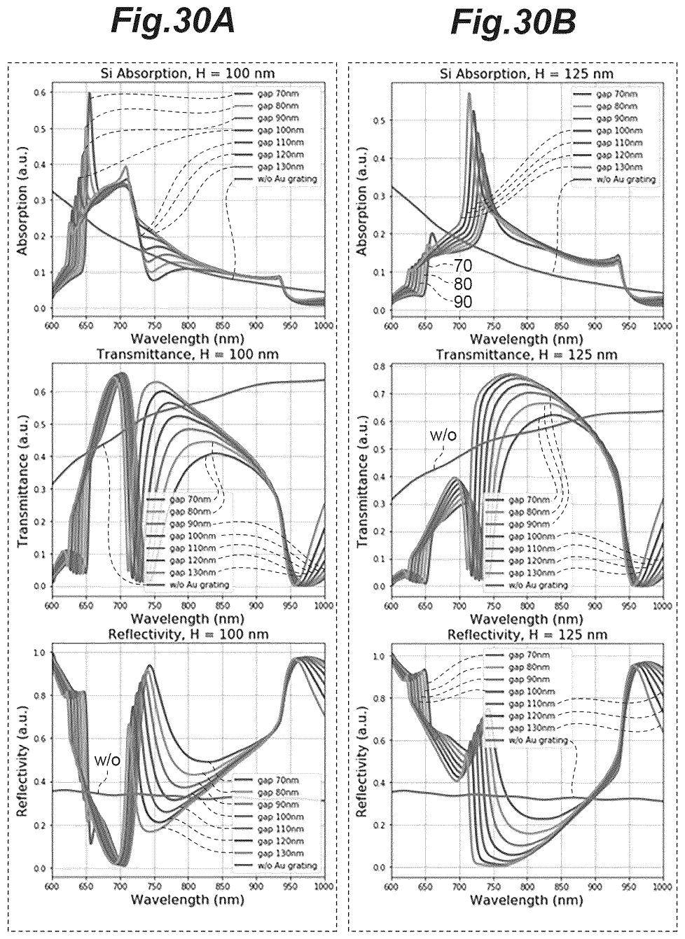

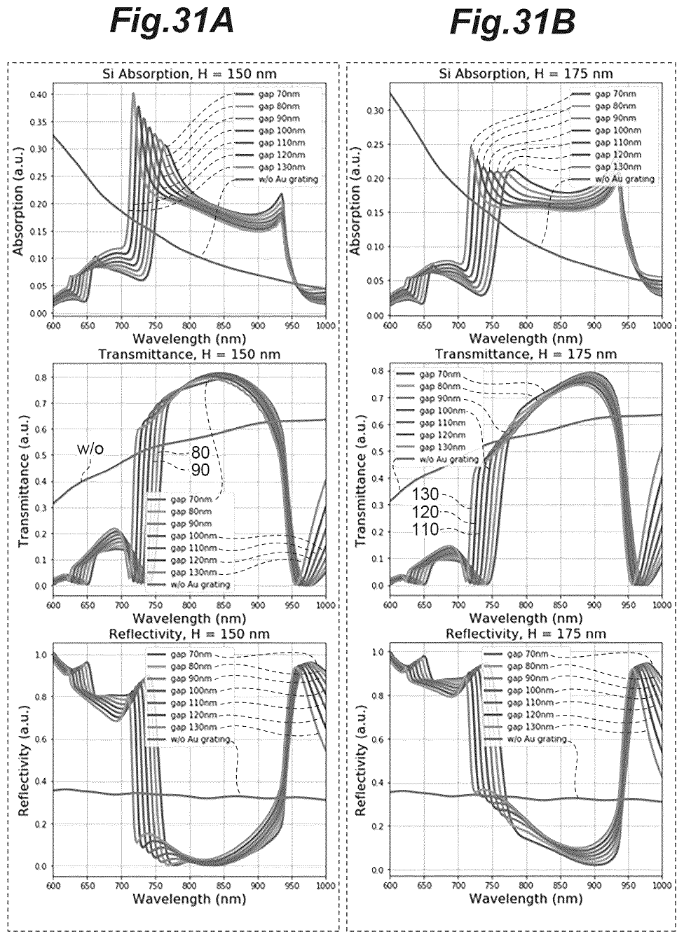

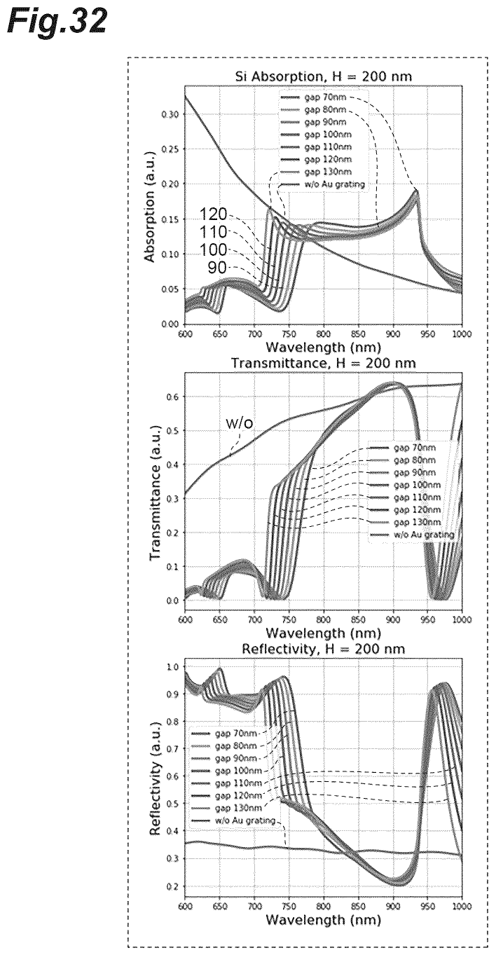

FIGS. 26A to 32 are graphs showing the relationships between the wavelength and the absorption, the transmittance, and the reflectivity when the angle θ is 77.5° (A tan (4.5)) and the period P is 520 nm in the second example (where the side surface 21c is inclined) shown in FIG. 4. FIGS. 26A to 29 are graphs when the gap is 20 nm to 60 nm, and FIGS. 30A to 32 are graphs when the gap is 70 nm to 130 nm. FIGS. 26A, 26B, 27A, 27B, 28A, 28B, and 29 are graphs when the height H is 100 nm, 125 nm, 150 nm, 175 nm, 200 nm, 225 nm, and 250 nm, respectively. FIGS. 30A, 30B, 31A, 31B, and 32 are graphs when the height H is 100 nm, 125 nm, 150 nm, 175 nm, and 200 nm, respectively. Other points are the same as those in the cases of FIGS. 7A to 11B.

From FIGS. 26A to 32, it can be seen that when the height H is in the range of 150 nm to 230 nm (225 nm), the reflectivity at the target wavelength is lower than that in a case where the plasmonic structure portion 20 is not provided and accordingly, localized surface plasmon resonance can occur in the plasmonic structure portion 20.

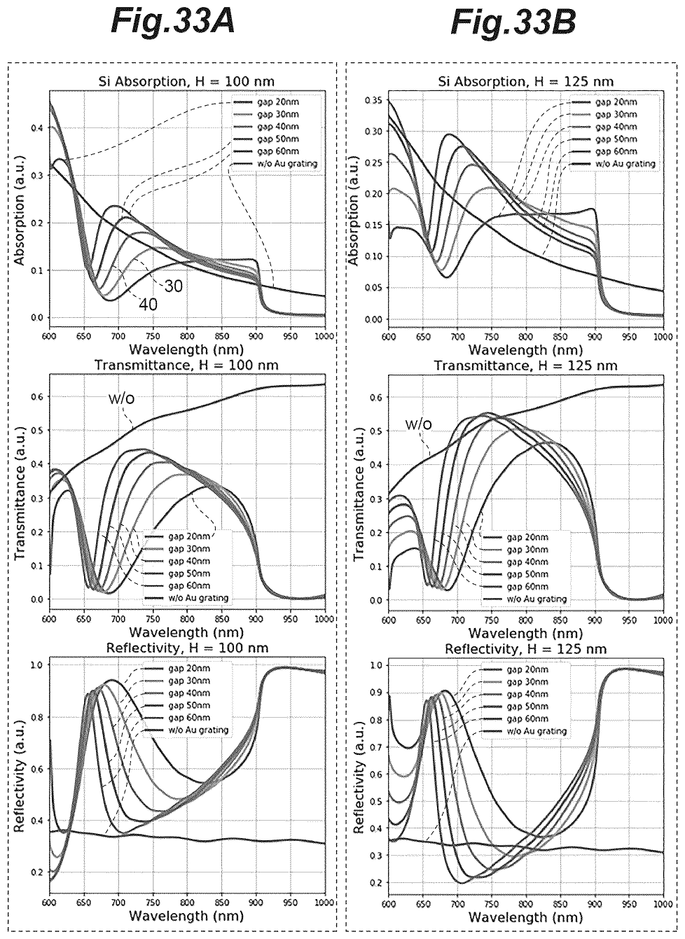

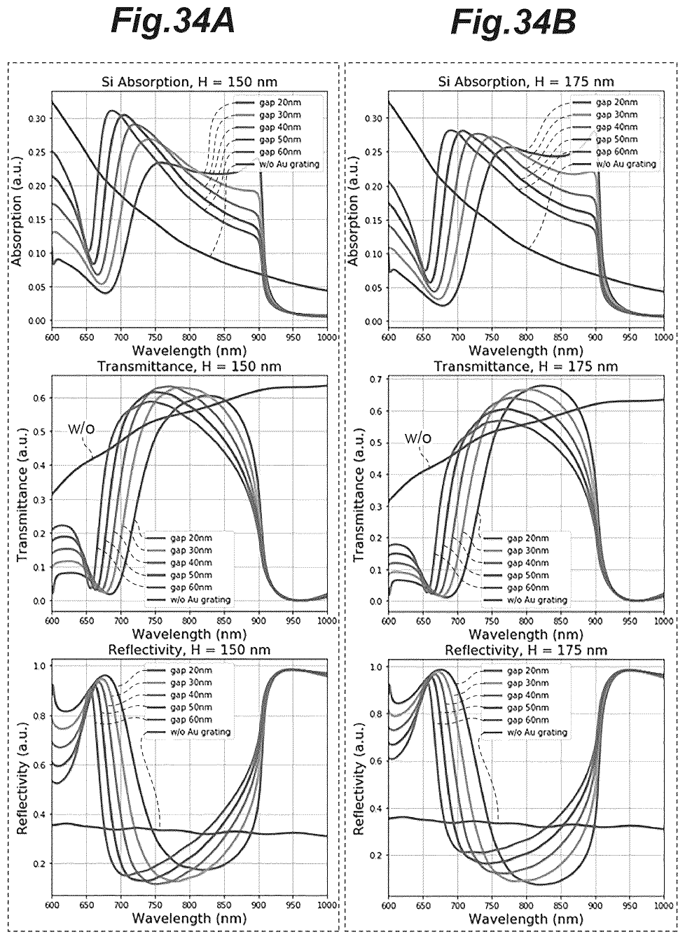

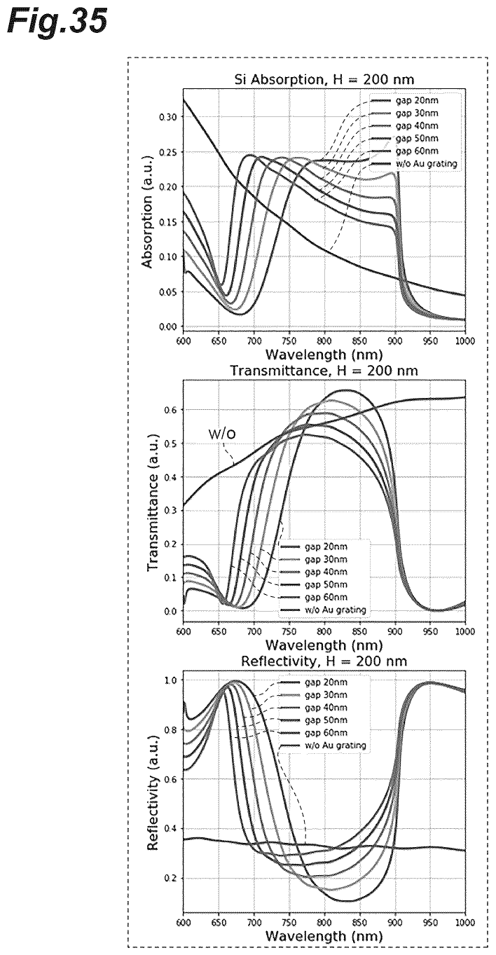

FIGS. 33A to 35 are graphs showing the relationships between the wavelength and the absorption, the transmittance, and the reflectivity when the angle θ is 77.5° (A tan (4.5)) and the period P is 250 nm in the second example (where the side surface 21c is inclined) shown in FIG. 4. FIGS. 33A, 33B, 34A, 34B, and 35 are graphs when the height H is 100 nm, 125 nm, 150 nm, 175 nm, and 200 nm, respectively. Other points are the same as those in the cases of FIGS. 7A to 11B.

From FIGS. 33A to 35, it can be seen that when the height H is in the range of 125 nm to 200 nm, the reflectivity at the target wavelength is lower than that in a case where the plasmonic structure portion 20 is not provided and accordingly, localized surface plasmon resonance can occur in the plasmonic structure portion 20.

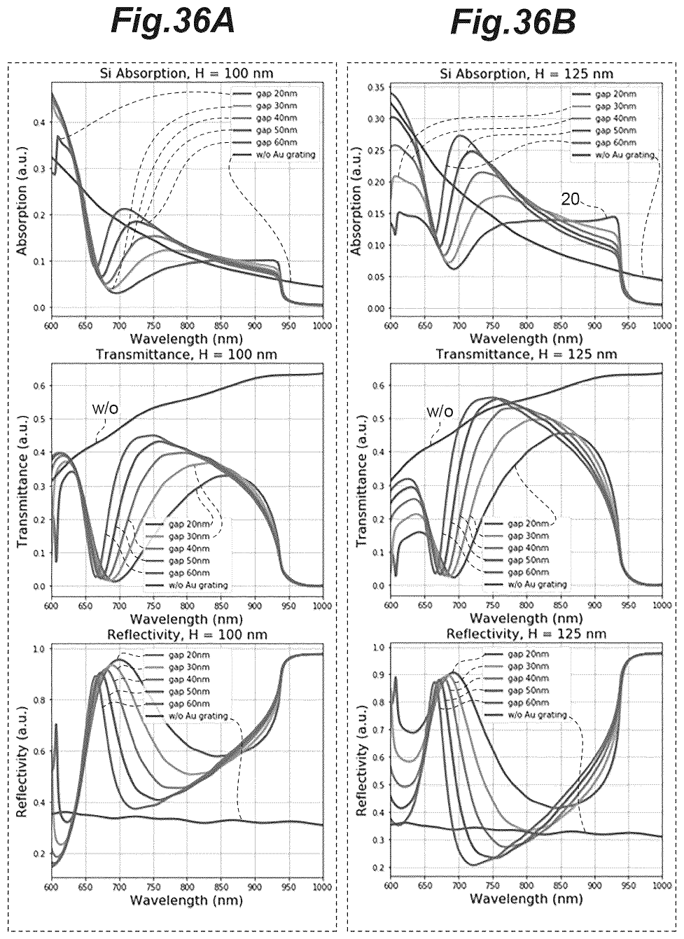

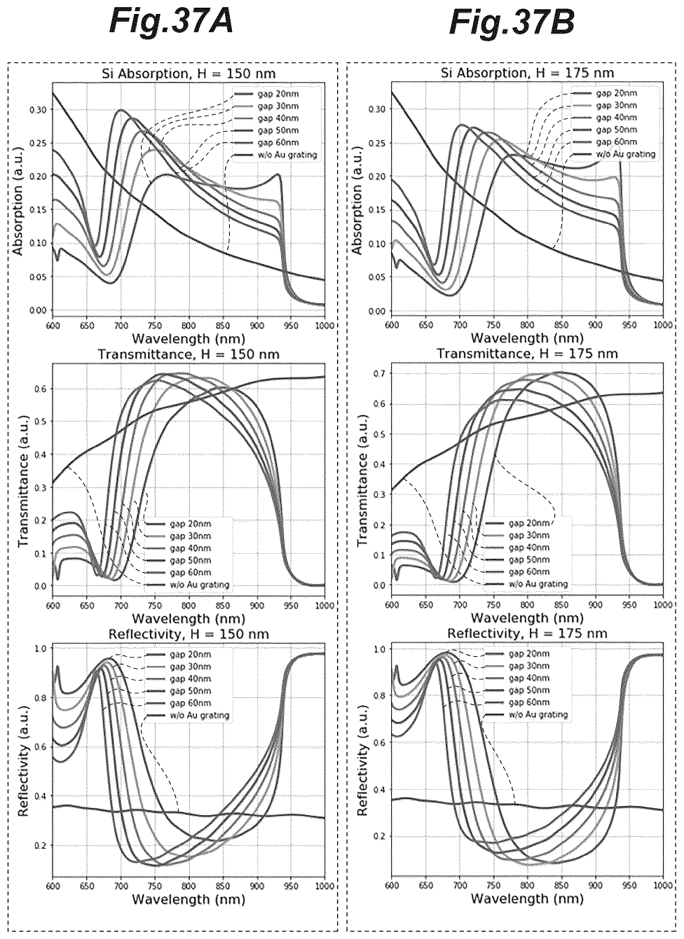

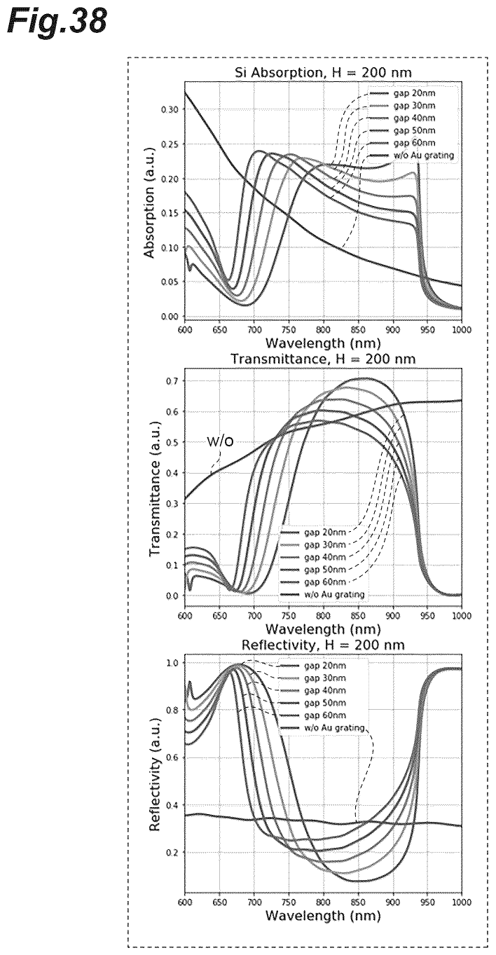

FIGS. 36A to 38 are graphs showing the relationships between the wavelength and the absorption, the transmittance, and the reflectivity when the angle θ is 77.5° and the period P is 260 nm in the second example. FIGS. 36A, 36B, 37A, 37B, and 38 are graphs when the height H is 100 nm, 125 nm, 150 nm, 175 nm, and 200 nm, respectively. Other points are the same as those in the cases of FIGS. 7A to 11B.

From FIGS. 36A to 38, it can be seen that when the height H is in the range of 125 nm to 200 nm, the reflectivity at the target wavelength is lower than that in a case where the plasmonic structure portion 20 is not provided and accordingly, localized surface plasmon resonance can occur in the plasmonic structure portion 20.

From the results in FIGS. 18A to 25, the results in FIGS. 26A to 32, the results in FIGS. 33A to 35, and the results in FIGS. 36A to 38, it can be seen that in the second example in which the side surface 21c is inclined, localized surface plasmon resonance can occur when the height His in the range of 125 nm to 230 nm and accordingly, incident light can be diffracted appropriately. Although not shown, a similar calculation was also performed for the case where the angle θ was 77.5° and the period P was 270 nm, 280 nm, and 500 nm in the third example, and it was confirmed that the same results were obtained.

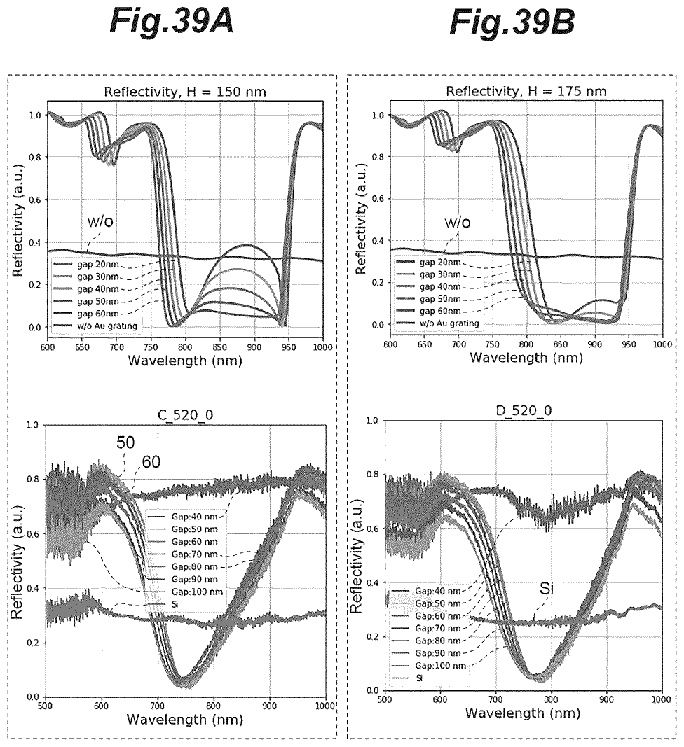

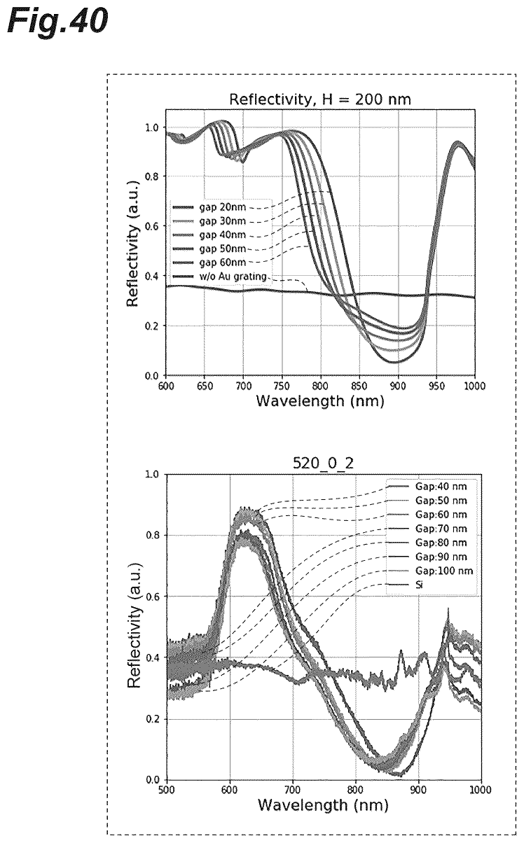

FIGS. 39A to 40 are graphs showing the relationships between the wavelength and the absorption, the transmittance, and the reflectivity when the angle θ is 77.5° and the period P is 520 nm in the second example (where the side surface 21c is inclined) shown in FIG. 4. An upper graph in FIG. 39A shows calculation results when the height H is 150 nm, and a lower graph in FIG. 39A shows measurement results when the height H is 150 nm. An upper graph in FIG. 39B shows calculation results when the height H is 175 nm, and a lower graph in FIG. 39B shows measurement results when the height H is 175 nm. An upper graph in FIG. 40 shows calculation results when the height H is 200 nm, and a lower graph in FIG. 40 shows measurement results when the height H is 200 nm. The calculation results are the simulation results described above.

From FIGS. 39A to 40, it can be seen that the calculation results and the measurement results show similar trends in all cases where the height H is 150 nm, 175 nm, and 200 nm. This shows that the actual characteristics can be understood based on the simulation.

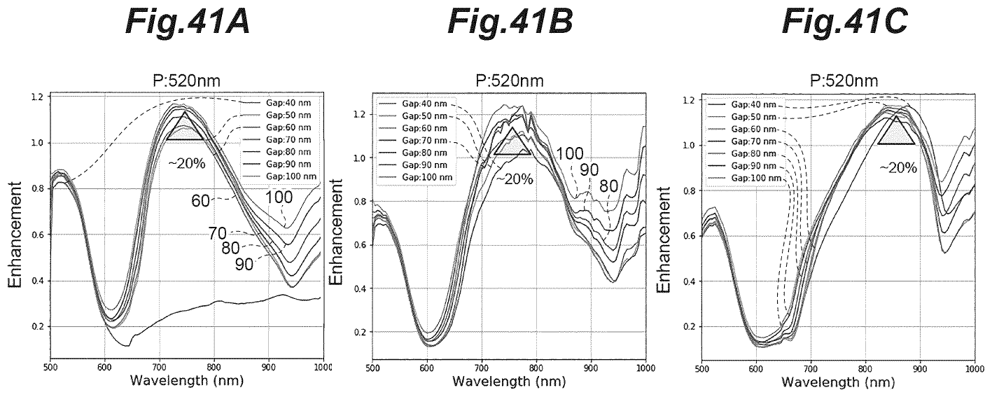

FIGS. 41A to 41C are graphs showing the relationship between the wavelength and the enhancement (light absorption rate) calculated based on the measurement results of FIGS. 39A to 40. FIGS. 41A to 41C are graphs when the height H is 150 nm, 175 nm, and 200 nm, respectively. In each graph, the enhancement is the ratio of the amount of light absorption calculated with the amount of light absorption when the plasmonic structure portion 20 is not provided as 1 (reference). As shown in FIGS. 41A to 41C, the enhancement at the target wavelength is improved by about 20% in all cases where the height H is 150 nm, 175 nm, and 200 nm. This shows that the enhancement (light absorption rate) can be improved by providing the plasmonic structure portion 20.

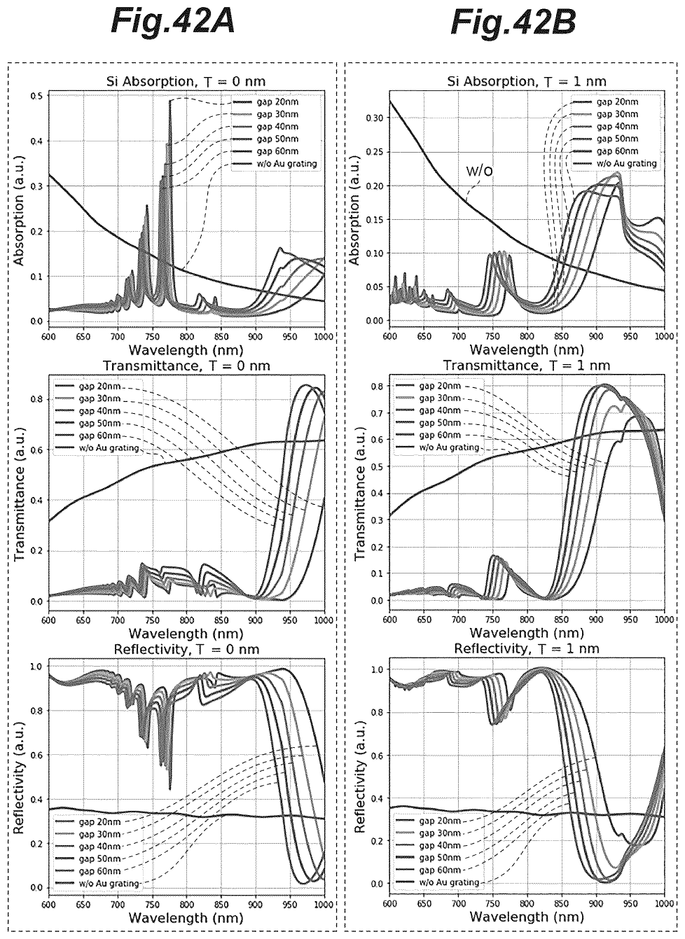

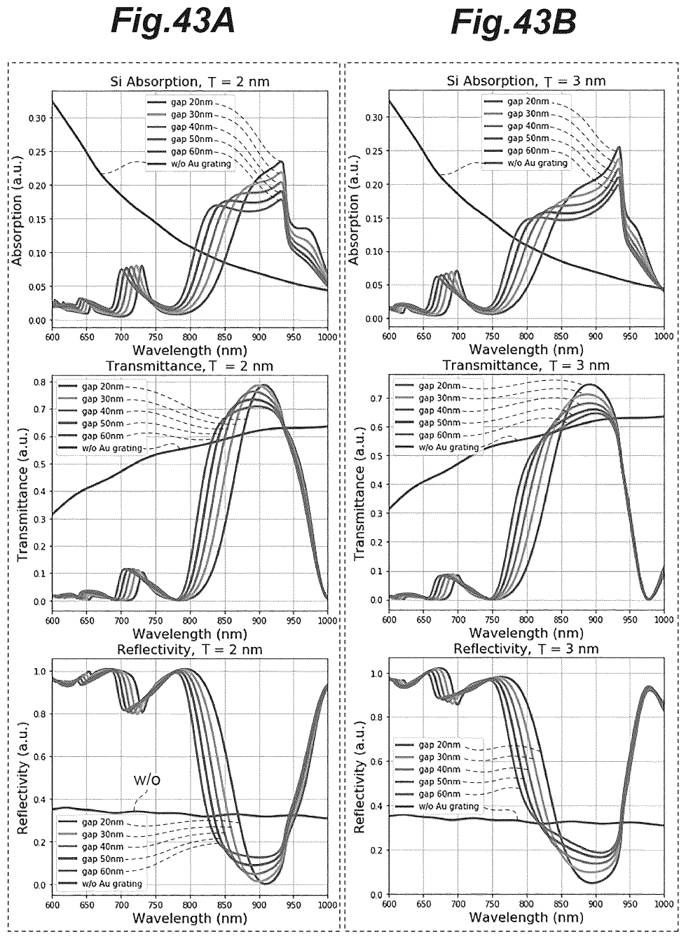

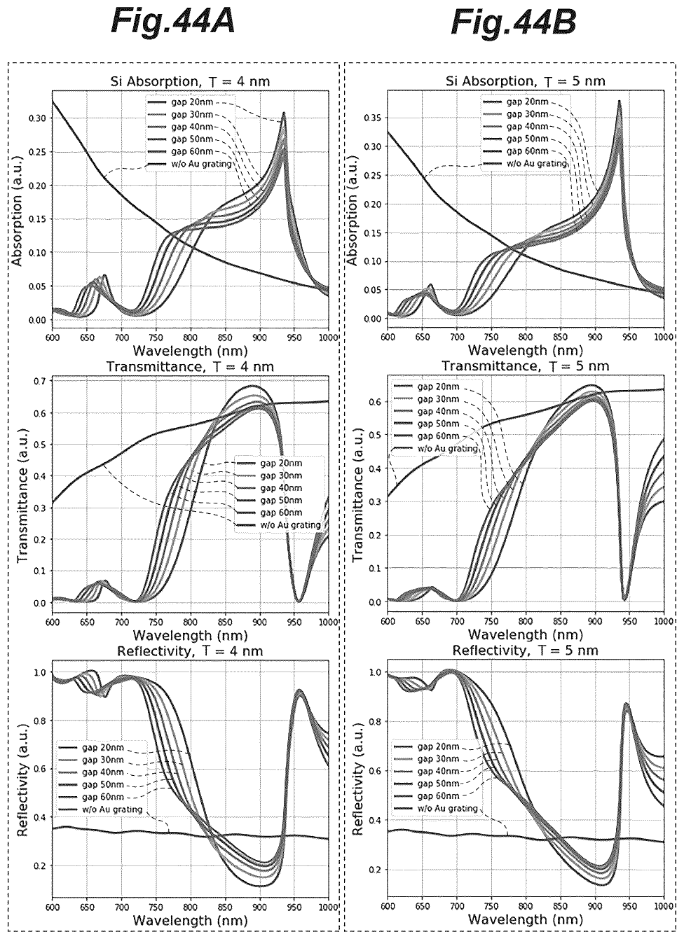

FIGS. 42A to 44B are graphs showing the relationships between the wavelength and the absorption, the transmittance, and the reflectivity when the presence or absence of the silicon dioxide layer 31 and its thickness are changed when the angle θ is 77.5° and the period P is 520 nm in the second example as shown in FIG. 4 (where the side surface 21c is inclined). FIG. 42A is a graph when there is no silicon dioxide layer, and FIGS. 42B, 43A, 43B, 44A, and 44B are graphs when the thickness (T) of the silicon dioxide layer 31 is 1 nm, 2 nm, 3 nm, 4 nm, and 5 nm, respectively. The height H of the unit structure 21 was set to 200 nm. Other points are the same as those in the cases of FIGS. 7A to 11B.

From FIGS. 42A to 44B, it can be seen that the reflectivity decreases in different wavelength ranges when the thickness of the silicon dioxide layer 31 is different. This shows that localized surface plasmon resonance can occur in a desired wavelength range by adjusting the thickness of the silicon dioxide layer 31.

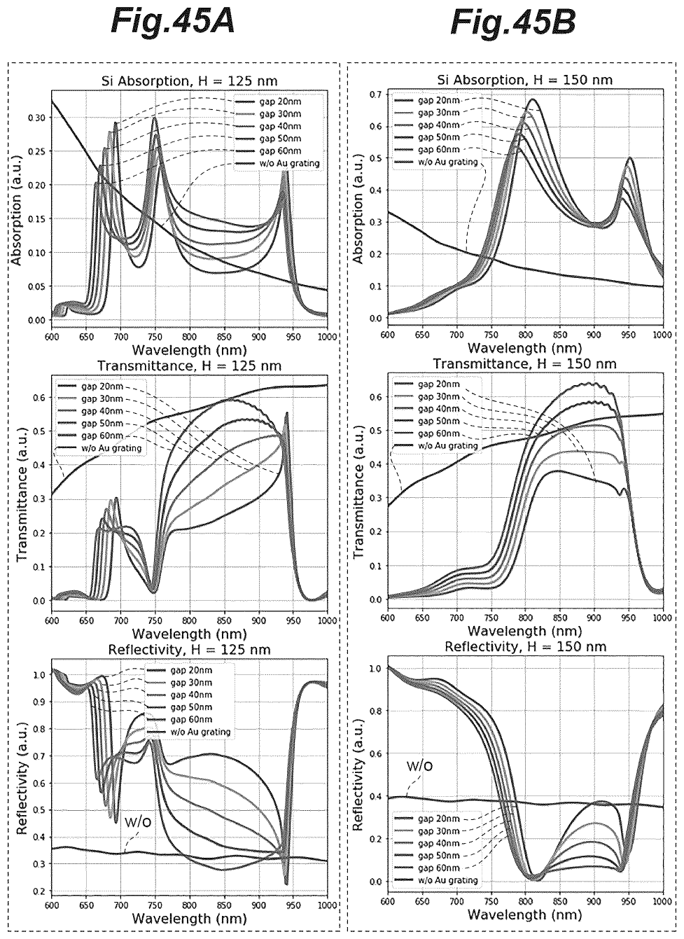

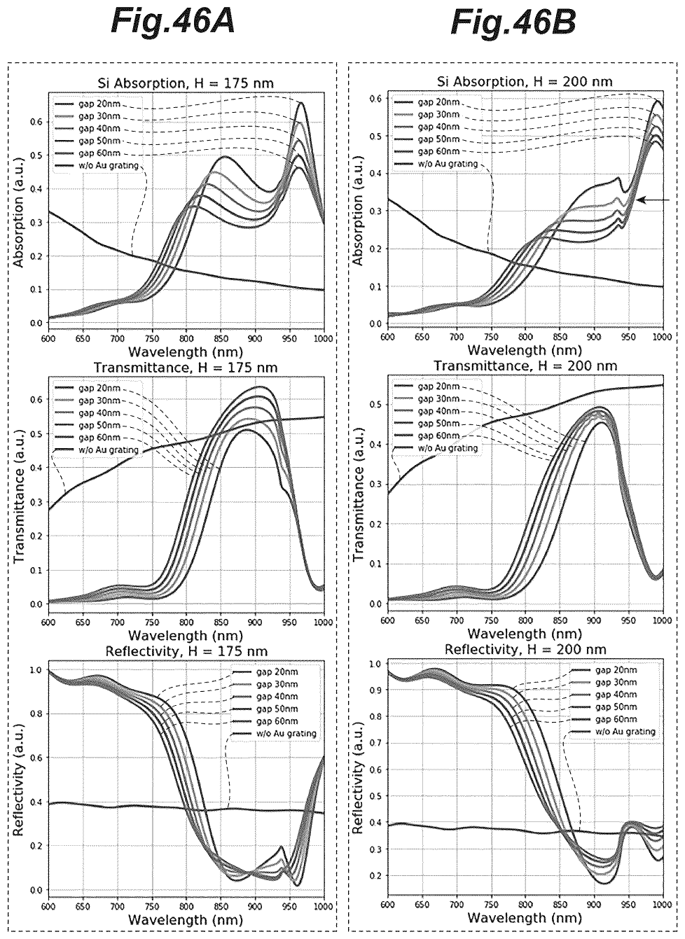

FIGS. 45A to 46B are graphs showing the relationships between the wavelength and the absorption, the transmittance, and the reflectivity when the angle θ is 80.5°, the period P is 520 nm, and the adhesion layer 32 formed of titanium is provided in the second example (where the side surface 21c is inclined) shown in FIG. 4. FIGS. 45A, 45B, 46A, and 46B are graphs when the height H is 125 nm, 150 nm, 175 nm, and 200 nm, respectively. Other points are the same as those in the cases of FIGS. 7A to 11B.

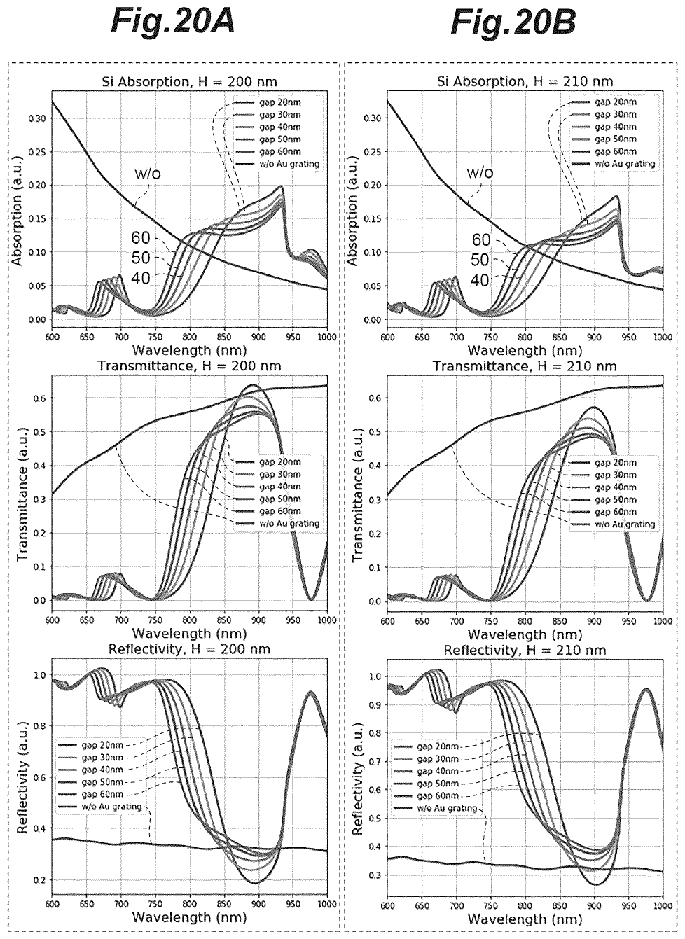

When comparing the graphs of the corresponding height H between FIGS. 45A to 46B (where the adhesion layer 32 is provided) and FIGS. 18A to 22B (where the adhesion layer 32 is not provided), it can be seen that the graphs in FIGS. 45A to 46B show an improvement in the enhancement (light absorption rate) compared to the corresponding graphs in FIGS. 18A to 22B. For example, when comparing the point indicated by the arrow in the upper absorption graph in FIG. 46B with the corresponding point in the upper absorption graph in FIG. 20A, it can be seen that the absorption is about two times higher. This shows that the enhancement can be improved by providing the adhesion layer 32 formed of titanium. In addition, by providing the adhesion layer 32, the bonding strength (degree of adhesion) between the plasmonic structure portion 20 and the silicon dioxide layer 31 can be increased.

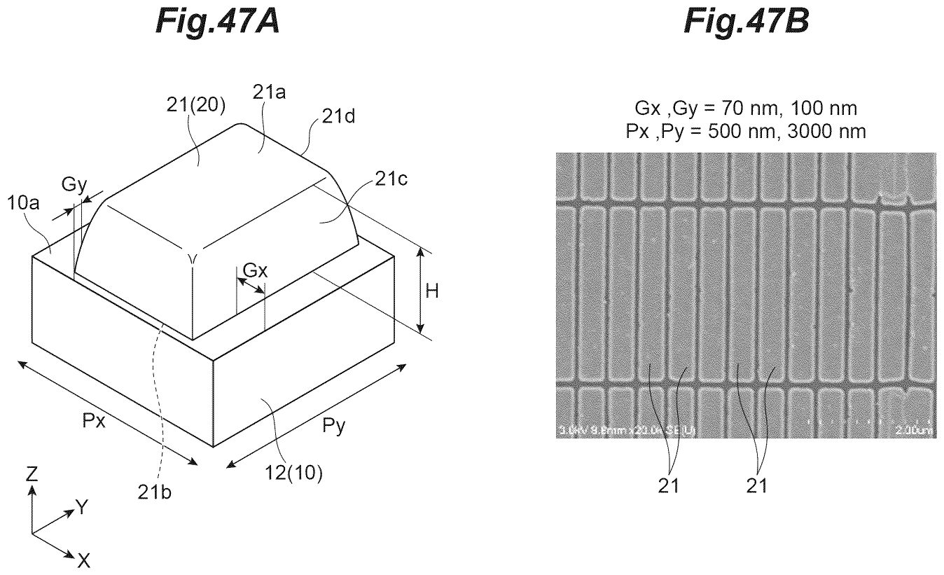

The plasmonic structure portion 20 may be configured as in a first modification example shown in FIGS. 47A and 47B. In the first modification example, the unit structure 21 has a shape that is elongated in the Y direction. That is, the length of the unit structure 21 in the Y direction is larger than the length of the unit structure 21 in the X direction. In this example, the unit structure 21 is formed in a rectangular shape in plan view. FIG. 47B is a photograph of the unit structure 21 when Px is 500 nm, Py is 3000 nm, Gx is 70 nm, and Gy is 100 nm. In the first modification example, the side surface 21c may be formed vertically as in the first example shown in FIG. 3, or may be inclined as in the second example shown in FIG. 4. Gy may be 0. That is, the unit structures 21 may be continuously formed along the Y direction without any discontinuities.

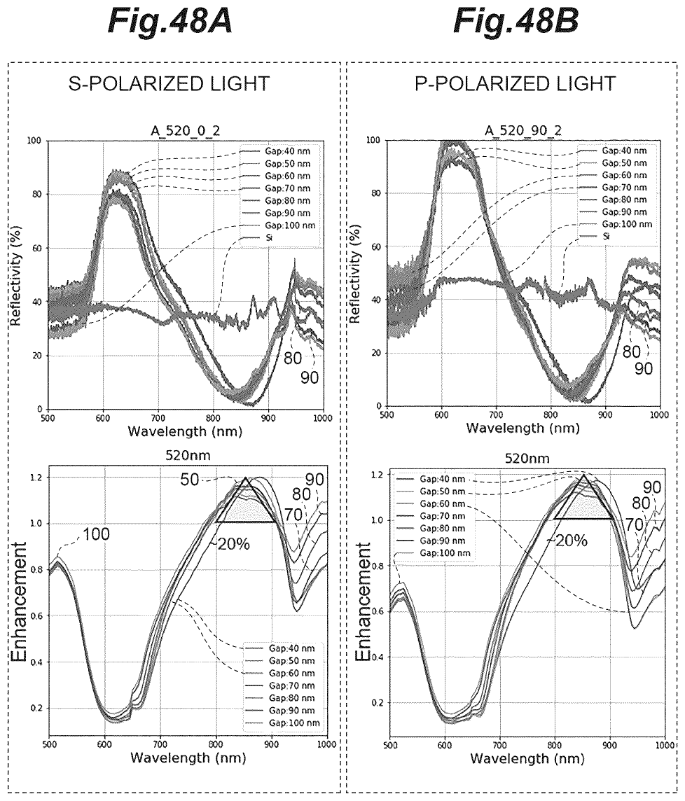

FIGS. 48A and 48B are graphs when the angle θ is 77.5°, the period P is 520 nm, and the height H is 200 nm in the second example (where the side surface 21c is inclined) shown in FIG. 4. FIG. 48A is a graph showing the relationships between the wavelength and the reflectivity and the enhancement for S-polarized light, and FIG. 48B is a graph showing the relationships between the wavelength and the reflectivity and the enhancement for P-polarized light. The oscillation direction of S-polarized light is parallel to the Y direction, and the oscillation direction of P-polarized light is parallel to the X direction.

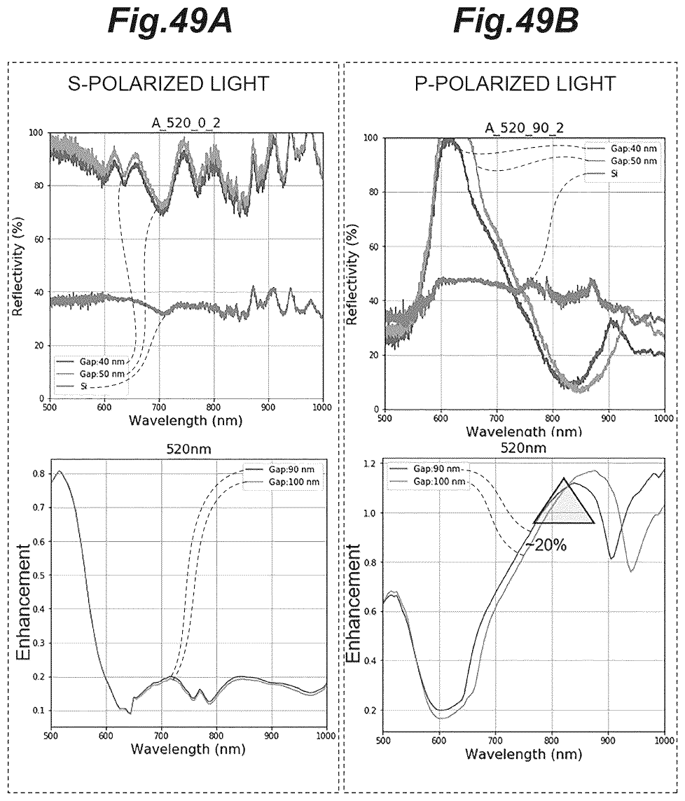

FIGS. 49A and 49B are graphs when the side surface 21c is inclined so that the angle θ is 77.5°, the period P is 520 nm, and the height H is 200 nm in the first modification example. FIG. 49A is a graph showing the relationships between the wavelength and the reflectivity and the enhancement for S-polarized light, and FIG. 49B is a graph showing the relationships between the wavelength and the reflectivity and the enhancement for P-polarized light. The oscillation direction of S-polarized light is parallel to the Y direction, and the oscillation direction of P-polarized light is parallel to the X direction (FIG. 47A).

As shown in FIGS. 48A and 48B, when the unit structure 21 has a square shape, both S-polarized light and P-polarized light are diffracted by the plasmonic structure portion 20. On the other hand, as shown in FIGS. 49A and 49B, when the unit structure 21 has a rectangular shape, P-polarized light is diffracted by the plasmonic structure portion 20, while S-polarized light is reflected without being diffracted by the plasmonic structure portion 20. Thus, in the first modification example, one of the P-polarized light and the S-polarized light can be diffracted by the plasmonic structure portion 20, while the other light can be reflected by the plasmonic structure portion 20. Such a function can be used to separate signal light from noise light, for example, in fields such as LiDAR (Light Detection and Ranging).

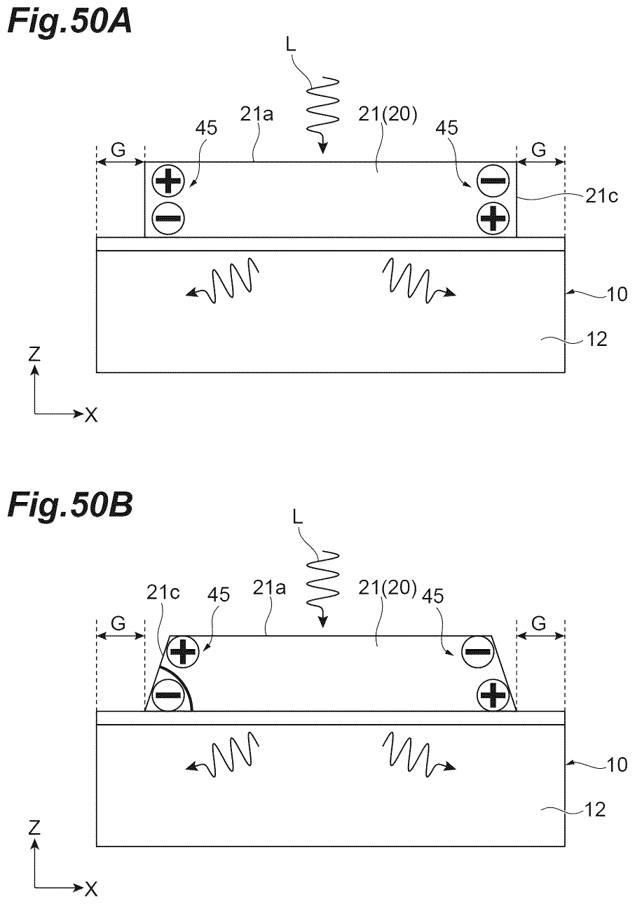

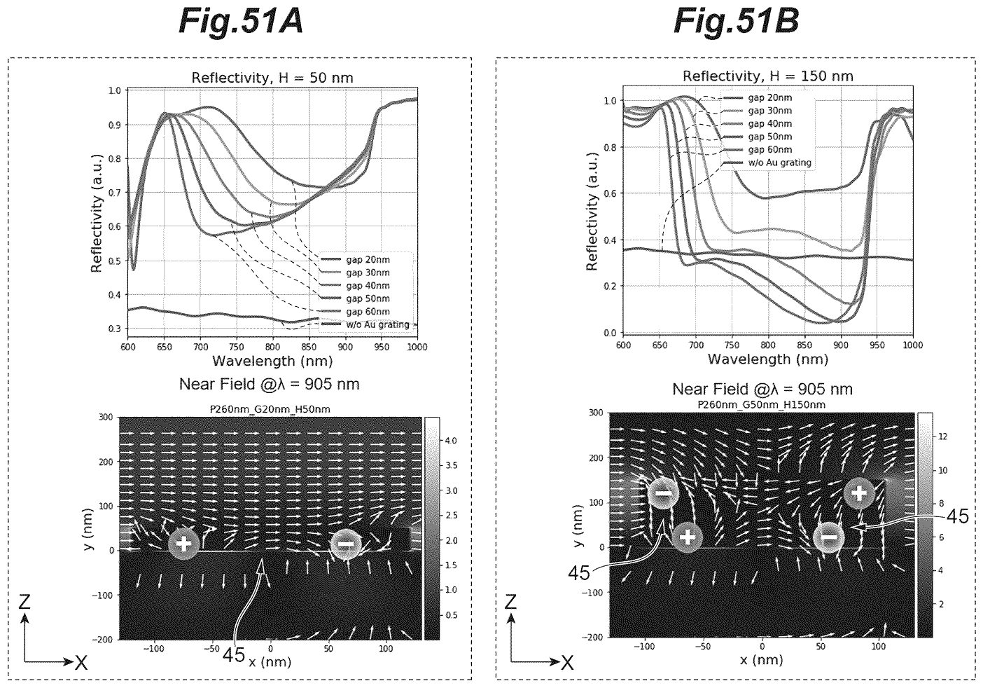

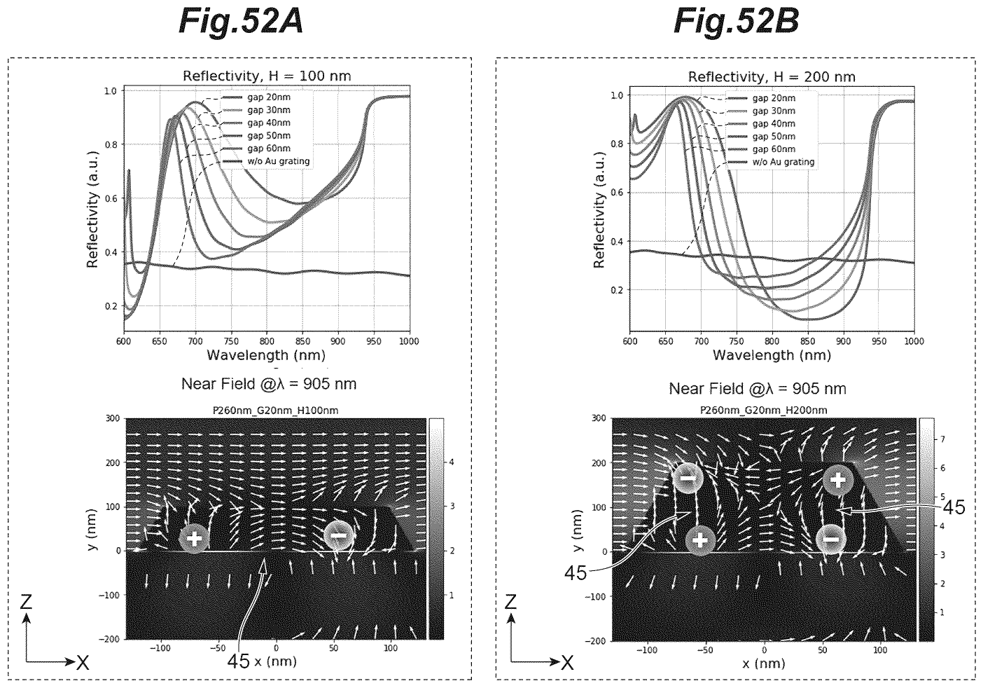

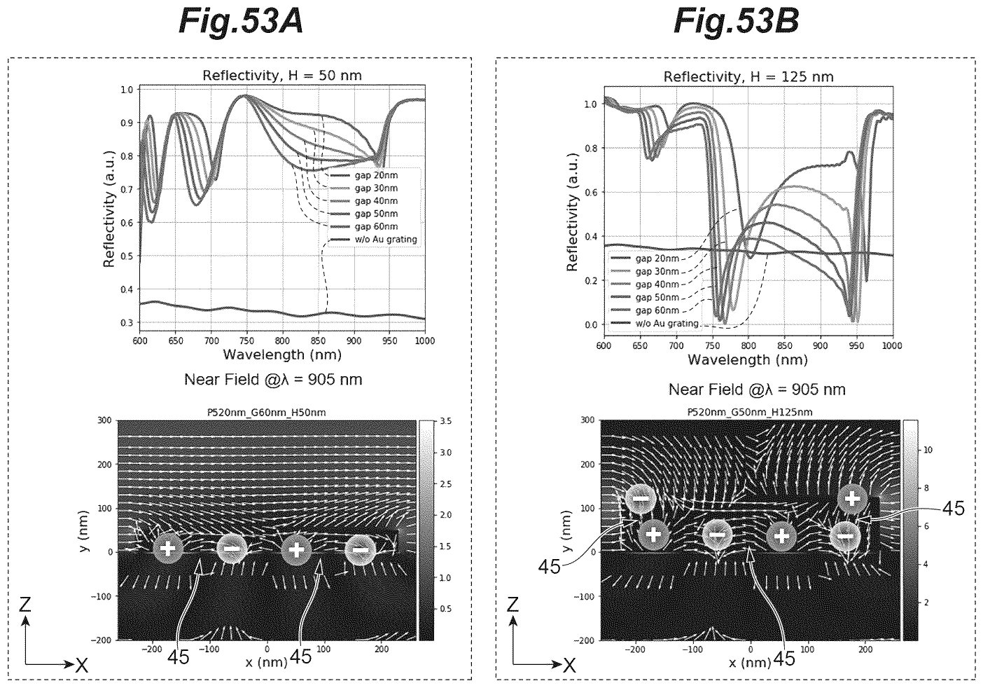

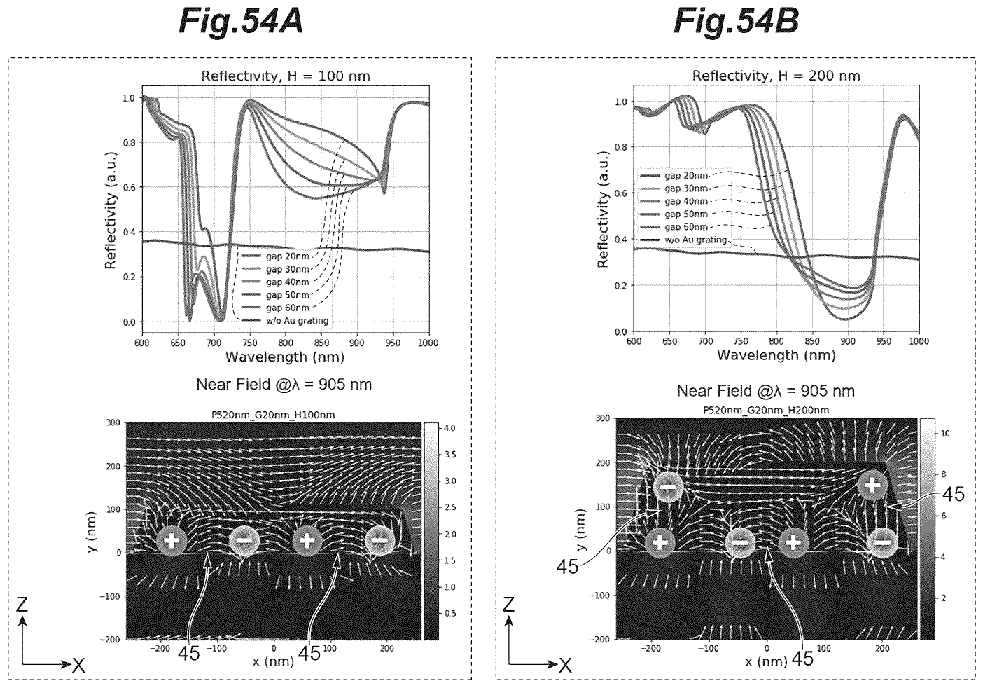

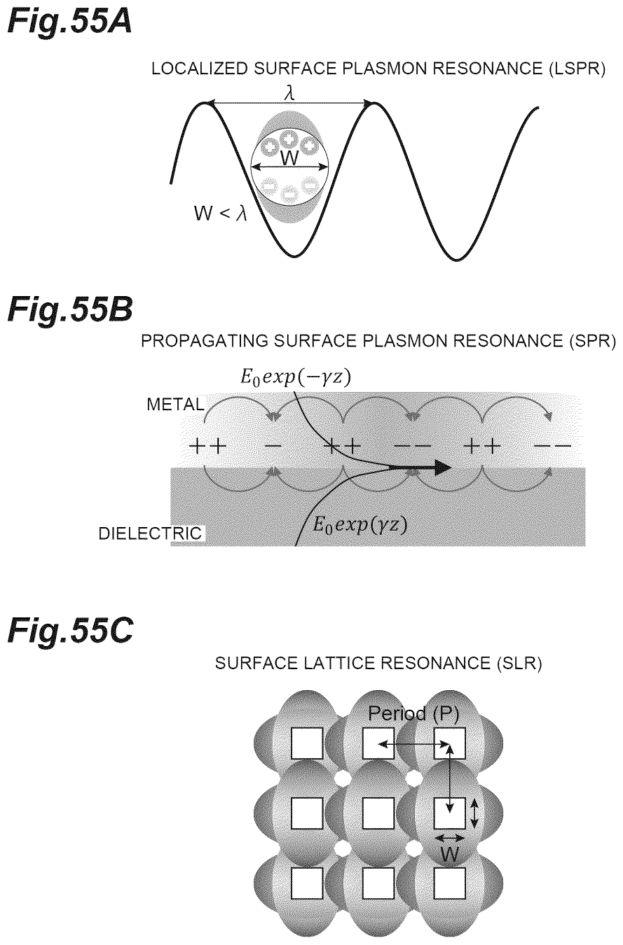

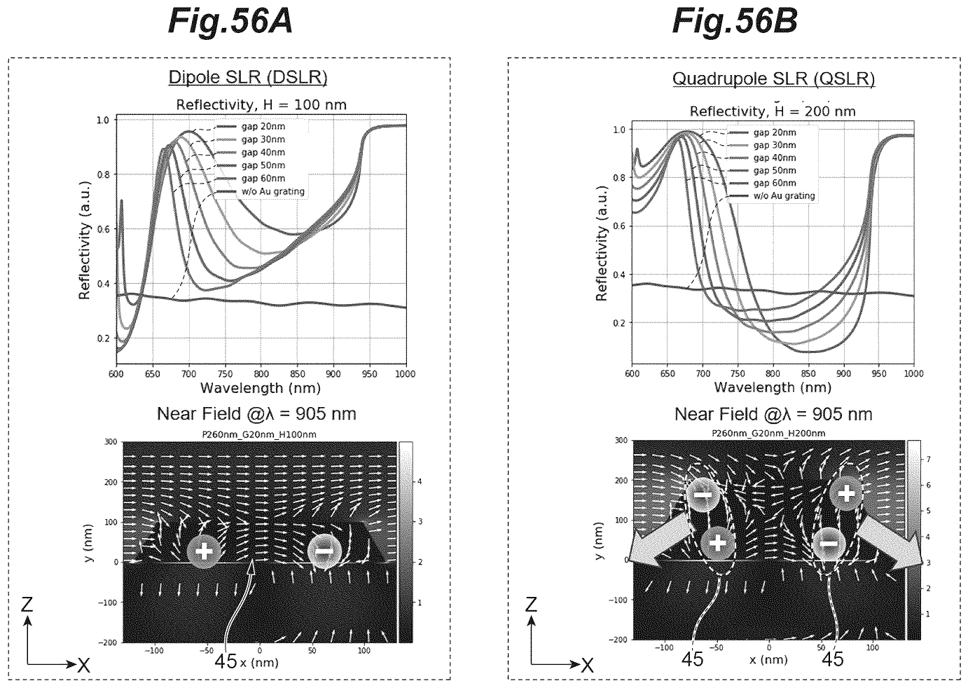

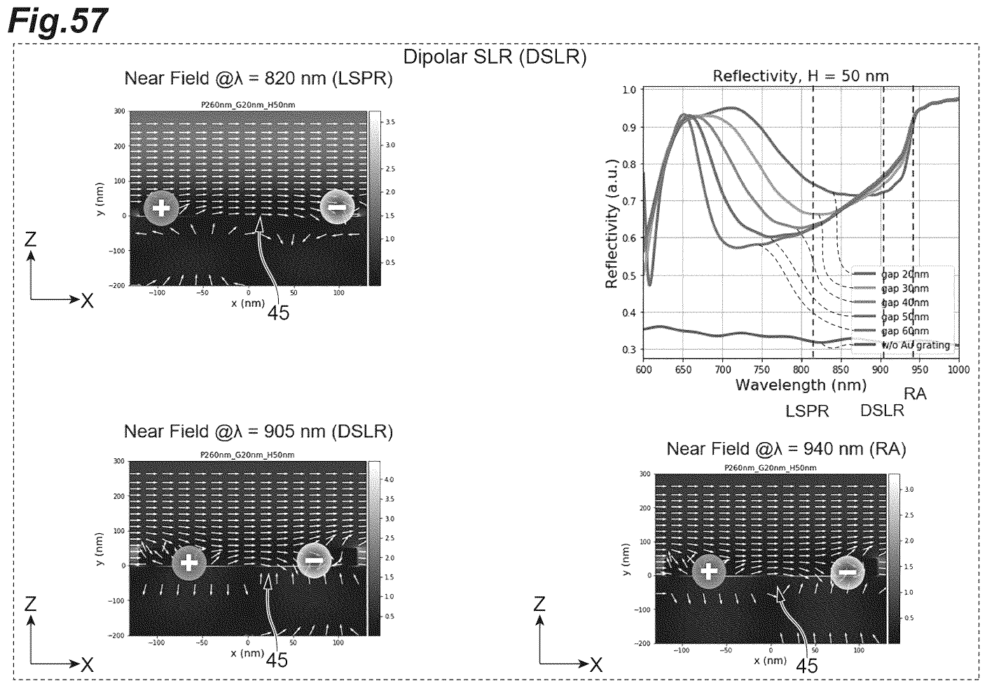

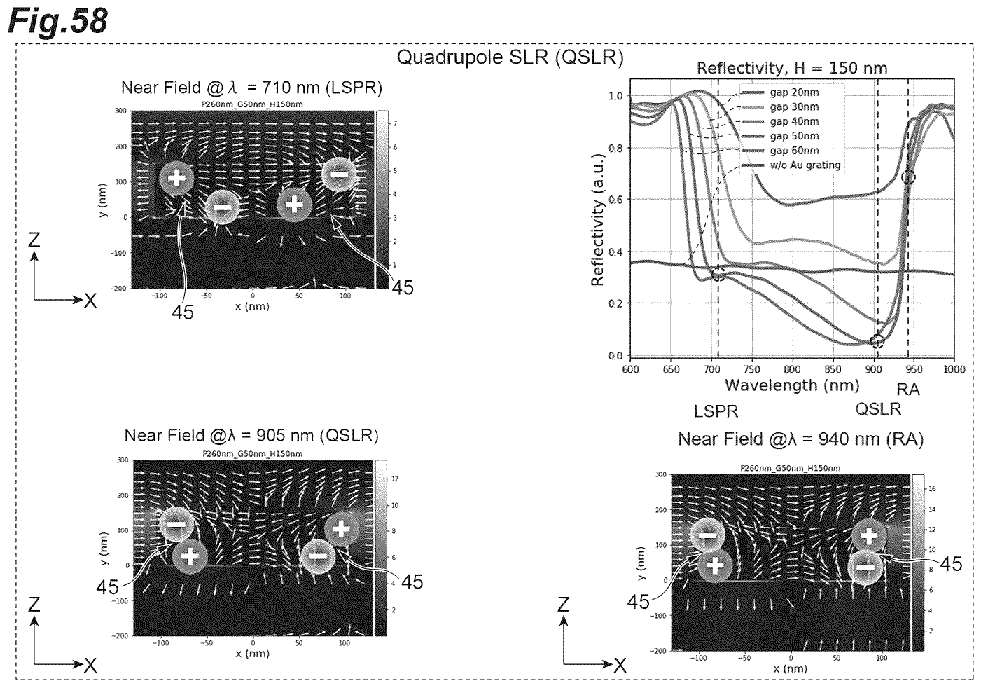

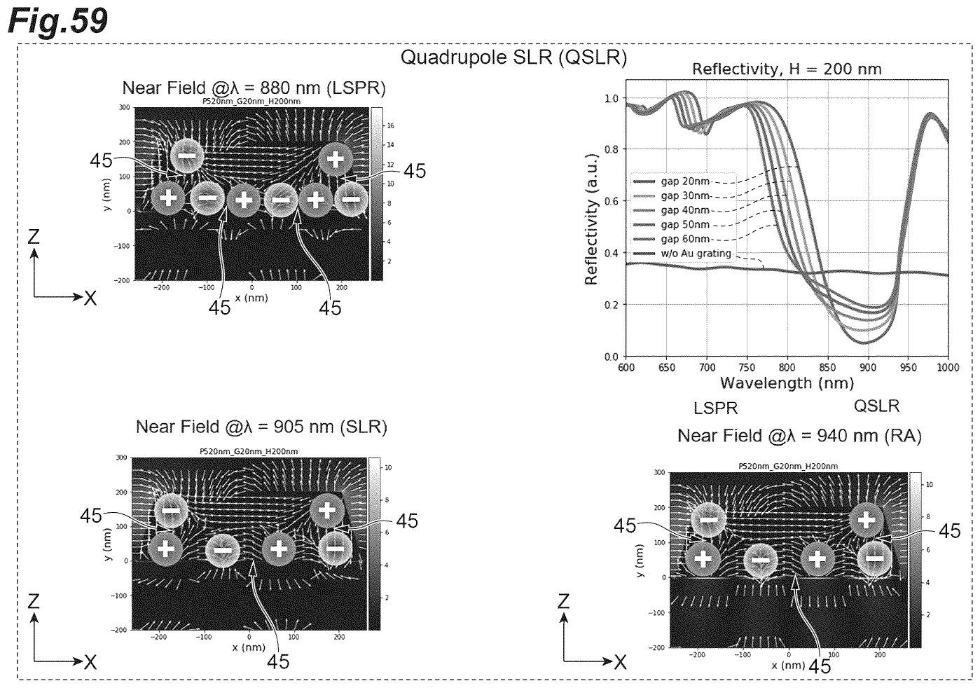

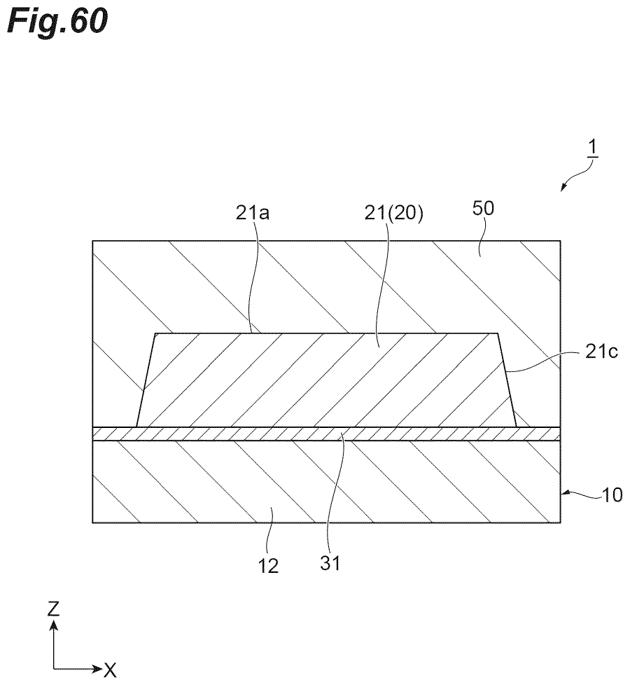

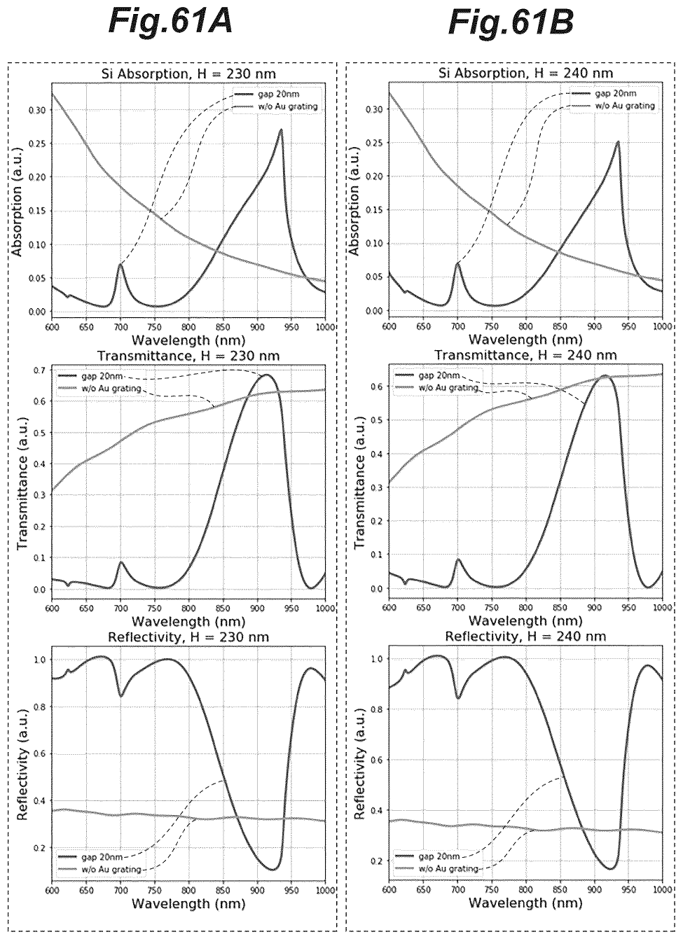

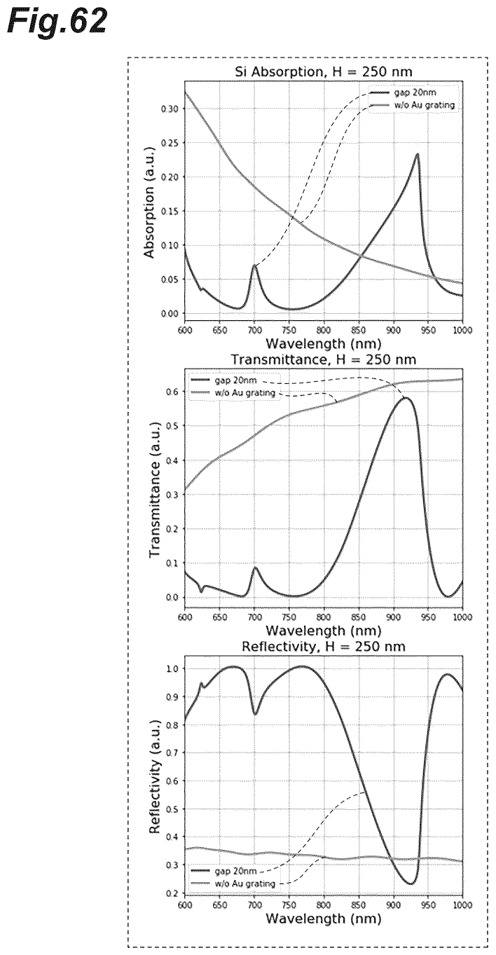

FIG. 50A is a diagram showing an example of an electric field mode (electric field vector) in the first example, and FIG. 50B is a diagram showing an example of an electric field mode in the second example. As shown in FIG. 50A, in the first example, an electric field mode is formed in the plasmonic structure portion 20 so that the dipole 45 extends along the Z direction. As shown in FIG. 50B, in the second example, an electric field mode is formed in the plasmonic structure portion 20 so that the dipole 45 extends at an angle inclined with respect to the Z direction. In both cases, the light L is diffracted so as to travel in a direction crossing the Z direction.

FIGS. 51A to 54B are diagrams for explaining the relationship between whether or not an electric field mode (not perpendicular to the Z direction), in which the dipole 45 extends along the Z direction or at an angle inclined with respect to the Z direction, is formed in the plasmonic structure portion 20 and the height H of the unit structure 21. FIGS. 51A to 52B show results for the first-order diffracted light output from the plasmonic structure portion 20. FIGS. 51A and 51B show results when the height H is 50 nm and 150 nm in the first example, and FIGS. 52A and 52B show results when the height H is 100 nm and 200 nm in the second example.

As shown in FIG. 51A, in the first example, when the height H is 50 nm, the dipole 45 extends perpendicular to the Z direction (parallel to the light incidence surface). On the other hand, as shown in FIG. 51B, when the height H is 150 nm, the dipole 45 extends at an angle inclined with respect to the Z direction. As shown in FIG. 52A, in the second example, when the height H is 100 nm, the dipole 45 extends perpendicular to the Z direction (parallel to the light incidence surface). On the other hand, as shown in FIG. 52B, when the height H is 200 nm, the dipole 45 extends at an angle inclined with respect to the Z direction.

FIGS. 53A to 54B show results for the second-order diffracted light output from the plasmonic structure portion 20. FIGS. 53A and 53B show results when the height H is 50 nm and 125 nm in the first example, and FIGS. 54A and 54B show results when the height H is 100 nm and 200 nm in the second example.

As shown in FIG. 53A, in the first example, when the height H is 50 nm, the dipole 45 extends perpendicular to the Z direction (parallel to the light incidence surface). On the other hand, as shown in FIG. 53B, when the height H is 125 nm, there is the dipole 45 that extends at an angle inclined with respect to the Z direction. As shown in FIG. 54A, in the second example, when the height H is 100 nm, the dipole 45 extends perpendicular to the Z direction (parallel to the light incidence surface). On the other hand, as shown in FIG. 54B, when the height H is 200 nm, there is the dipole 45 that extends at an angle inclined with respect to the Z direction.

The localized surface plasmon resonance will be described with reference to FIGS. 55A to 59. Examples of surface plasmon resonance include localized surface plasmon resonance, propagating surface plasmon resonance, and surface lattice resonance. In Localized Surface Plasmon Resonance (LSPR) shown in FIG. 55A, collective oscillations of free electrons are excited in a specific wavelength range, depending on the structure shape and size (W), in a structure that is sufficiently smaller than the wavelength (λ). As a result, scattered light (radiated light) is enhanced in a specific wavelength range. Propagated surface plasmon resonance (SPR) shown in FIG. 55B is based on a different principle from localized surface plasmon resonance. When evanescent waves are coupled together with an interface as a boundary, a wave that propagates across the interface is generated. A prism or a grating is required for this coupling.

Surface lattice resonance (SLR) shown in FIG. 55C occurs due to a combination of localized surface plasmon resonance and propagating surface plasmon resonance. Specifically, surface lattice resonance occurs when diffracted light at the lattice interface and localized surface plasmons interfere with each other. A high Q value is achieved by exciting propagating surface plasmons through localized surface plasmons. The photodetector 1 according to the embodiment utilizes this surface lattice resonance. The localized surface plasmon resonance depends on the structure shape, and the propagating surface plasmon resonance depends on the structure period. The surface lattice resonance depends on both the structure shape and the structure period. That is, in the photodetector 1 of the embodiment, localized surface plasmons that depend on the shape of the plasmonic structure portion 20 are also excited while propagating surface plasmons that depend on the period P are excited, thereby generating lattice surface plasmon resonance.

FIGS. 56A and 56B correspond to FIGS. 52A and 52B. The electric field mode in which the dipole 45 extends perpendicular to the Z direction (parallel to the light incidence surface) in FIG. 56A is dipolar SLR (DSLR) generated by the coupling of a dipole and SPR. In the plasmonic structure portion, light is emitted perpendicular to the extending direction of the dipole. In this case, since the diffracted light travels parallel to the light incidence surface, it is not possible to diffract light appropriately. In contrast, the electric field mode in which the dipole 45 extends along the Z direction or at an angle inclined with respect to the Z direction in FIG. 56B is quadrupole SLR (SLR) generated by the coupling of a quadrupole and SPR. In the plasmonic structure portion, light is emitted perpendicular to the extending direction of the dipole. In this case, therefore, it is possible to diffract light appropriately as indicated by the arrows in the diagram.

FIG. 57 is a diagram for explaining the electric field mode in the case of dipolar SLR, and FIGS. 58 and 59 are diagrams for explaining the electric field mode in the case of quadrupole SLR. FIG. 57 corresponds to FIG. 51A. As shown in FIG. 57, when the height H is 50 nm in the first example, the dipole 45 extends perpendicular to the Z direction (parallel to the light incidence surface) at all wavelengths, generating dipolar SLR. FIG. 58 corresponds to FIG. 51B. As shown in FIG. 58, when the height H is 150 nm in the second example, the dipole 45 extends along the Z direction or at an angle inclined with respect to the Z direction at all wavelengths, generating quadrupole SLR. FIG. 59 corresponds to FIG. 54B. As shown in FIG. 59, when the height H is 200 nm in the first example, there is the dipole 45 that extends along the Z direction or at an angle inclined with respect to the Z direction at all wavelengths, generating dipolar SLR. RA in FIG. 57 stands for Rayleigh anomaly, which is an abnormal transmission phenomenon that occurs with the same period as the wavelength. FIGS. 57 to 59, the resonance dip is excited in the order of SPR (propagating surface plasmon resonance), SLR (surface lattice resonance), and LSPR (localized surface plasmon) from the long wavelength side. In FIG. 57, the excitation wavelengths of RA and SPR are 940 nm, the excitation wavelength of DSLR is 905 nm, and the excitation wavelength of LSPR is 820 nm.

As in a second modification example shown in FIG. 60, the photodetector 1 may further include a protective layer 50 that covers the plasmonic structure portion 20. The protective layer 50 covers the entire plasmonic structure portion 20, and is provided so as to enter (be inserted) between the unit structures 21 adjacent to each other. The protective layer 50 is, for example, a silicon dioxide or aluminum oxide (Al₂O₃) film, and is an ALD film formed by atomic layer deposition. By providing the protective layer 50, it is possible to increase the physical and chemical durability of the plasmonic structure portion 20 and to further provide a predetermined optical element on the protective layer 50. The protective layer 50 may be provided only between the unit structures 21 adjacent to each other.

### Function and Effect

In the photodetector 1, the APD 10 has the p-type semiconductor region 15 (first semiconductor region) and the n-type semiconductor region 16 (second semiconductor region) that is formed on a side of the semiconductor region 15 opposite to the light incidence surface 10a to form a pn junction with the semiconductor region 15. In such a so-called PonN-type structure in which a p-type semiconductor region is formed on an n-type semiconductor region, the amount of light absorption in the p-type semiconductor region tends to be small. In this regard, in the photodetector 1, the optical path length in the p-type semiconductor region 15 can be increased by diffracting the incident light using the plasmonic structure portion 20. As a result, the amount of light absorption can be increased to improve quantum efficiency. In addition, in the photodetector 1, each unit structure 21 forming the plasmonic structure portion 20 has the top surface 21a, the bottom surface 21b and the side surface 21c, and the height H of each unit structure 21 is 100 nm or more and 250 nm or less. Therefore, since localized surface plasmon resonance can occur in the plasmonic structure portion 20, incident light can be diffracted appropriately. As a result, the above-described function and effect of increasing the amount of light absorption to improve quantum efficiency can be noticeably achieved. Therefore, according to the photodetector 1, it is possible to improve quantum efficiency. In addition, as described above, in the first example, localized surface plasmon resonance occurs when the height H is in the range of 100 nm to 150 nm. In the second example, when the angle θ is 80.5°, localized surface plasmon resonance can occur when the height H is in the range of 125 nm to 210 nm. In the second example, when the angle θ is 77.5°, localized surface plasmon resonance can occur when the height H is in the range of 150 nm to 230 nm. Therefore, it is considered that when the angle θ is further decreased, the range of the height H for generating the localized surface plasmon resonance increases. In addition, for example, when the unit structure 21 is formed by lift-off, the height H may be limited to approximately 250 nm. In addition, if the height H is too large, the light absorption in the plasmonic structure portion 20 may increase. For this reason as well, the height H can be set to 250 nm or less.

FIGS. 61A to 62 are graphs showing the relationships between the wavelength and the absorption, the transmittance, and the reflectivity when the angle θ is 71.6° (A tan (3.0)) and the period P is 520 nm in the second example. FIGS. 61A, 61B, and 62 are graphs when the height His 230 nm, 240 nm, and 250 nm, respectively. From FIGS. 61A to 62, it can be seen that when the angle θ is 71.6° and the height H is in the range of 230 nm to 250 nm, the reflectivity at the target wavelength is lower than that in a case where the plasmonic structure portion 20 is not provided and accordingly, localized surface plasmon resonance can occur in the plasmonic structure portion 20. In addition, taking this result and the results described above into consideration, it can be seen that in the second example in which the side surface 21c is inclined, localized surface plasmon resonance can occur when the height H is in the range of 125 nm to 250 nm and accordingly, the incident light can be diffracted appropriately.

In the first example shown in FIG. 3, the side surface 21c of each unit structure 21 may be formed perpendicular to the light incidence surface 10a, and the height H of each unit structure 21 may be 100 nm or more and 150 nm or less. In this case, since the localized surface plasmon resonance can occur, the incident light can be diffracted appropriately.

In the second example shown in FIG. 4, the side surface 21c of each unit structure 21 is inclined so as to widen toward the bottom surface 21b. Therefore, it is possible to widen the wavelength range in which surface plasmon resonance occurs. In addition, for example, when a shape defect occurs at the boundary between the top surface 21a and the side surface 21c during the manufacturing process (for example, when corners are chipped or rounded), the desired function may not be achieved. However, when the side surface 21c is inclined, the effect of such a shape defect can be suppressed compared to, for example, when the side surface 21c is formed vertically.

In the second example, the height H of each unit structure 21 may be 125 nm or more and 250 nm or less. In this case, since localized surface plasmon resonance can occur, incident light can be diffracted appropriately.

In the photodetector 1, in each unit structure 21, the top surface 21a and the side surface 21c are connected to each other through the curved surface 21d. Therefore, since the plasmonic structure portion 20 is not easily broken even when an external force is applied, it is possible to improve the stability of the photodetector 1.

Between the plasmonic structure portion 20 and the semiconductor region 15, the silicon dioxide layer 31 is formed. Therefore, it is possible to generate surface plasmon resonance in a desired wavelength range by adjusting the thickness of the silicon dioxide layer 31.

Between the plasmonic structure portion 20 and the silicon dioxide layer 31, the adhesion layer 32 formed of a metal material is formed. Therefore, it is possible to increase the bonding strength between the plasmonic structure portion 20 and the silicon dioxide layer 31.

In the APD 10, the trench 17 that reflects light diffracted by the plasmonic structure portion 20 is formed so as to surround the semiconductor region 15 in plan view. Therefore, it is possible to further increase the optical path length in the semiconductor region 15 by reflecting light using the trench 17.

In the first modification example described above, in plan view, a plurality of unit structures 21 are arranged along the X direction (first direction), and each unit structure 21 has a shape that is elongated in the Y direction (second direction) perpendicular to the X direction. In this case, for example, one of the P-polarized light and the S-polarized light can be diffracted by the plasmonic structure portion 20, while the other light can be reflected by the plasmonic structure portion 20.

The plasmonic structure portion 20 (unit structure 21) is formed of a metal material. Therefore, the plasmonic structure portion 20 can have a function as a wavelength filter that transmits only light having a specific wavelength.

In the example described above, the plasmonic structure portion 20 is configured so that the second-order diffracted light travels at an angle of 70° or more and less than 90° with respect to the Z direction (direction perpendicular to the light incidence surface 10a). Therefore, for example, compared to a case where the first-order diffracted light is used, it is possible to secure the size of the plasmonic structure portion 20. As a result, it is possible to secure the manufacturing accuracy.

In the second modification example, the plasmonic structure portion 20 is covered with the protective layer 50, and the protective layer 50 enters between the unit structures 21 adjacent to each other. Therefore, it is possible to increase the physical and chemical durability of the plasmonic structure portion 20 and to further provide a predetermined optical element on the protective layer 50.

The thickness of the silicon dioxide layer 31 is 1 nm or more and 5 nm or less. Therefore, the above-described function and effect that the surface plasmon resonance can occur in a desired wavelength range by adjusting the thickness of silicon dioxide layer 31 are noticeably achieved.

The adhesion layer 32 is a titanium layer. Therefore, it is possible to improve the enhancement (light absorption rate).

The present disclosure is not limited to the above-described embodiment and modification examples. For example, the materials and shapes of the respective components are not limited to the materials and shapes described above, and various materials and shapes can be adopted. The silicon dioxide layer 31 may be omitted, and the plasmonic structure portion 20 may be formed directly on the light incidence surface 10a. The trench 17 may be omitted. The curved surface 21d may be omitted, and a sharp corner may be formed at the boundary between the top surface 21a and the side surface 21c.

In the example described above, the plasmonic structure portion 20 is configured so that the second-order diffracted light (positive and negative second-order diffracted light) travels at an angle of 70° or more and less than 90° with respect to the Z direction. However, the plasmonic structure portion 20 may be configured so that the first-order diffracted light (positive and negative first-order diffracted light) travels at an angle of 70° or more and less than 90° with respect to the Z direction. That is, the first-order diffracted light may be used instead of the second-order diffracted light. However, when the first-order diffracted light is used, the size of the plasmonic structure portion 20 needs to be reduced, which may result in a decrease in manufacturing accuracy. In other words, when the second-order diffracted light is used, the size of the plasmonic structure portion 20 can be secured, and accordingly, the manufacturing accuracy can be improved.

In the embodiment and each modification example described above, the APD 10 may be of NonP type. That is, similarly to the structure shown in FIG. 5B, in the APD 10, the semiconductor region 13 may be of p-type, the semiconductor region 14 may be of p-type, the semiconductor region 15 (first semiconductor region) may be of n-type, and the semiconductor region 16 (second semiconductor region) may be of p-type. That is, the APD 10 may be of either PonN type or NonP type. As described above, when the PonN type is adopted, it is possible to improve the time resolution and the sensitivity. On the other hand, when the plasmonic structure portion 20 is provided in the NonP type, it is possible to increase the optical path length in the light absorption region and accordingly increase the amount of light absorption, compared to the case where the plasmonic structure portion 20 is not provided in the NonP type. Specifically, this can be expressed in the form of L=Leff*sin (90°−θ). L is the optical path length in the thickness direction of the Si film, Leff is an effective optical path length, and θ is a diffraction angle. In addition, the NonP-type structure can be appropriately used when light diffracted by the plasmonic structure portion 20 travels at an angle of, for example, 70° to 80° with respect to the Z direction. The reason will be described below. The diffraction angle at the plasmonic structure portion 20 (the angle at which light diffracted by the plasmonic structure portion 20 travels) is determined according to the period P and the wavelength of the light L. For example, when the period P is 260 nm and the wavelength is 905 nm (effective wavelength is 905 nm/3.6 (refractive index of Si)=251 nm), the diffraction angle is 75°. When the diffraction angle is small as described above, in the case of PonN type, the light absorption layer (semiconductor layer 41 in FIG. 5A) as a p-layer is extremely thin at a thickness of several hundreds of nm. Therefore, light may not be sufficiently absorbed. On the other hand, in the case of NonP type, the light absorption layer as a p-type layer (the semiconductor layer 44 and the p-type semiconductor layer on the substrate side in FIG. 5B) has a thickness of 1 μm or more. Therefore, it is possible to sufficiently absorb light. Thus, when the diffraction angle is large, for example, 70° to 80°, the NonP-type structure can be appropriately used. In the photodetector 1 according to the embodiment, the detection sensitivity can be effectively improved by adjusting the configuration of the plasmonic structure portion 20 according to the configuration of the APD 10 or the wavelength of the detection target.

What is claimed is:

1. A photodetector, comprising:
an avalanche photodiode including a light incidence surface on which light is incident; and
a plasmonic structure portion formed on the light incidence surface to diffract the light by surface plasmon resonance,
wherein the avalanche photodiode includes a p-type first semiconductor region and an n-type second semiconductor region formed on a side of the first semiconductor region opposite to the light incidence surface to form a pn junction with the first semiconductor region,
the plasmonic structure portion includes a plurality of unit structures arranged on the first semiconductor region,
each of the plurality of unit structures includes a top surface on a side opposite to the light incidence surface, a bottom surface facing the light incidence surface, and a side surface connected to the top surface and the bottom surface, and
a height of each of the plurality of unit structures is 100 nm or more and 250 nm or less.

2. The photodetector according to claim 1,
wherein the side surface of each of the plurality of unit structures is formed perpendicular to the light incidence surface, and
the height of each of the plurality of unit structures is 100 nm or more and 150 nm or less.

3. The photodetector according to claim 1,
wherein the side surface of each of the plurality of unit structures is inclined so as to widen toward the bottom surface.

4. The photodetector according to claim 3,
wherein the height of each of the plurality of unit structures is 125 nm or more and 250 nm or less.

5. The photodetector according to claim 1,
wherein, in each of the plurality of unit structures, the top surface and the side surface are connected to each other via a curved surface.

6. The photodetector according to claim 1,
wherein a silicon dioxide layer is formed between the plasmonic structure portion and the first semiconductor region.

7. The photodetector according to claim 6,
wherein an adhesion layer formed of a metal material is formed between the plasmonic structure portion and the silicon dioxide layer.

8. The photodetector according to claim 1,
wherein, in the avalanche photodiode, a trench for reflecting the light diffracted by the plasmonic structure portion is formed so as to surround the first semiconductor region when viewed from a direction perpendicular to the light incidence surface.

9. The photodetector according to claim 1,
wherein, when viewed from a direction perpendicular to the light incidence surface, the plurality of unit structures are arranged along a first direction, and each of the plurality of unit structures has a shape elongated in a second direction perpendicular to the first direction.

10. The photodetector according to claim 1,
wherein the plasmonic structure portion is configured so that second-order diffracted light travels at an angle of 70° or more and less than 90° with respect to a direction perpendicular to the light incidence surface.

11. The photodetector according to claim 1,
wherein the plasmonic structure portion is covered with a protective layer, and the protective layer enters between the unit structures adjacent to each other.

12. The photodetector according to claim 6,
wherein the silicon dioxide layer has a thickness of 1 nm or more and 5 nm or less.

13. The photodetector according to claim 7,
wherein the adhesion layer is a titanium layer.
